(19) United States
(12) Patent Application Publication
(10) Pub. No.: US 2026/0311741 A1
(43) Pub. Date: Oct. 8, 2026

(54) SEMICONDUCTOR MEMORY DEVICES WITH WORDLINE GROUPS

(71) Applicant: Samsung Electronics Co., Ltd., Suwon-si (KR)

(72) Inventors: Duckyoung Seo, Suwon-si (KR); Changyoung Lee, Suwon-si (KR); Kyu-Chang Kang, Suwon-si (KR); Young Seok Park, Suwon-si (KR)

(21) Appl. No.: 19/431,024

(22) Filed: Dec. 23, 2025

(30) Foreign Application Priority Data
Apr. 8, 2025 (KR) 10-2025-0045763

(51) Int. Cl. G11C 11/408; G11C 11/4091

(52) U.S. Cl. CPC G11C 11/4085; G11C 11/4091

(57) ABSTRACT

A semiconductor memory device includes a first semiconductor die and a second semiconductor die. The first semiconductor die and the second semiconductor die are stacked in a vertical direction. The first semiconductor die includes a first wordline group, a second wordline group, and a first backgateline. The first wordline group includes wordlines that are adjacent to each other and multiples of two. The first backgateline is disposed between the first wordline group and the second wordline group. The second semiconductor die includes a first sub-wordline driver group and a second sub-wordline driver group. The first sub-wordline driver group drives the first wordline group. The second sub-wordline driver group drives the second wordline group.

### CROSS-REFERENCE TO RELATED APPLICATION

This application claims priority under 35 U.S.C. § 119 to Korean Patent Application No. 10-2025-0045763 filed on April 8, 2025, in the Korean Intellectual Property Office, the entirety of which is incorporated by reference herein.

### BACKGROUND

Semiconductor memory devices may include volatile memory devices and non-volatile memory devices. Volatile memory devices may retain data while power is supplied, while non-volatile memory devices may retain the data even when power is cut off. Volatile memory devices are fast, and non-volatile memory devices are reliable and durable.

In recent years, to increase the storage capacity and the integration density of a semiconductor memory device, a vertical channel array transistor (VCAT) structure, which uses vertical channel transistors, is employed in memory cells of volatile memory devices, and a cell on periphery (COP) structure or a periphery on cell (POC) structure in which peripheral circuits for such memory cells are disposed below the memory cells has been developed.

### SUMMARY

However, in memory structures, such as VCAT structures, there is a problem in that coupling noise between adjacent wordlines increases and refresh characteristics decrease.

The present disclosure provides semiconductor memory devices, methods of operating the semiconductor memory devices, and memory systems including the semiconductor memory devices, capable of reducing coupling noises between adjacent wordlines to enhance refresh characteristics.

According to some implementations of the present disclosure, the semiconductor memory device includes a first semiconductor die and a second semiconductor die. The first semiconductor die and the second semiconductor die are stacked in a vertical direction. The first semiconductor die includes a first wordline group, a second wordline group, and a first backgateline. The first wordline group includes wordlines that are adjacent to each other and multiples of two. The first backgateline is disposed between the first wordline group and the second wordline group. The second semiconductor die includes a first sub-wordline driver group and a second sub-wordline driver group. The first sub-wordline driver group drives the first wordline group. The second sub-wordline driver group drives the second wordline group.

According to some implementations of the present disclosure, in the method for operating the semiconductor memory device, a first wordline group is driven by a first sub-wordline driver group. The second wordline group is driven by the second sub-wordline driver group. Each of the first wordline group and the second wordline group includes wordlines that are adjacent to each other and multiples of two, and a first backgateline is disposed between the first wordline group and the second wordline group.

According to some implementations of the present disclosure, the semiconductor memory system includes a memory controller and a semiconductor memory device. The semiconductor memory device operates under a control of the memory controller. The semiconductor memory device includes a first semiconductor die and a second semiconductor die. The first semiconductor die and the second semiconductor die are stacked in a vertical direction. The first semiconductor die includes odd-numbered wordline groups, even-numbered wordline groups, and a plurality of backgatelines. Each of the odd-numbered wordline groups includes wordlines that are adjacent to each other and multiples of two. Each of the even-numbered wordline groups includes wordlines that are adjacent to each other and multiples of two. The plurality of backgatelines are disposed one by one between one of the odd-numbered wordline groups and one of the even-numbered wordline groups. The second semiconductor die includes odd-numbered sub-wordline driver groups and even-numbered sub-wordline driver groups. The odd-numbered sub-wordline driver groups drive the odd-numbered wordline groups. The even-numbered sub-wordline driver groups drive the even-numbered wordline groups.

### BRIEF DESCRIPTION OF THE FIGURES

The above and other objects and features of the present disclosure will become apparent by describing in detail examples thereof with reference to the accompanying drawings.

FIG. 1 is a perspective view illustrating an example of a semiconductor memory device.

FIG. 2 is a flowchart illustrating an example of a method of operating a semiconductor memory device.

FIGS. 3A and 3B are diagrams illustrating examples of the semiconductor dies of FIG. 1.

FIG. 4 is a circuit diagram illustrating an example of memory cells.

FIG. 5 is a perspective view illustrating an example of a vertical channel array transistor (VCAT) structure.

FIG. 6 is a diagram illustrating an example of a configuration in which sub-wordline driver groups drive wordline groups.

FIGS. 7, 8, and 9 are diagrams illustrating examples of configurations in which sub-wordline driver groups drive wordline groups.

FIG. 10 is a diagram illustrating an example of a sub-memory cell array area.

FIG. 11A is a diagram illustrating an example of a sub-wordline driver and a bitline sense amplifier area.

FIG. 11B is a diagram illustrating an example of a configuration in which sub-wordline drivers drive wordlines.

FIG. 11C is a diagram illustrating an example of a configuration in which a sub-wordline driver and a wordline are connected.

FIG. 11D is a timing diagram illustrating an example of control signals for controlling a sub-wordline driver.

FIGS. 11E and 11F are diagrams illustrating upper metal pads and lower metal pads for connecting sub-wordline drivers and wordlines.

FIG. 12A is a diagram illustrating an example of a sub-wordline driver and a bitline sense amplifier area.

FIG. 12B is a diagram illustrating an example of a configuration in which sub-wordline drivers drive wordlines.

FIG. 13A is a diagram illustrating an example of a sub-wordline driver and a bitline sense amplifier area.

FIG. 13B is a diagram illustrating an example of a configuration in which sub-wordline drivers drive wordlines.

FIG. 14 is a block diagram illustrating an example of a semiconductor memory device.

FIG. 15 is a diagram illustrating an example of a semiconductor memory device.

FIG. 16 is a plan view illustrating an example of a pad array included in a semiconductor memory device.

FIG. 17A is a cross-sectional view of the semiconductor memory device of FIG. 15 taken along line A-A′.

FIG. 17B is a cross-sectional view of the semiconductor memory device of FIG. 15 taken along line B-B′.

FIG. 18 is a structural diagram illustrating an example of a semiconductor package including a semiconductor memory device.

FIG. 19 is a diagram illustrating an example of an electronic system including a semiconductor memory device.

### DETAILED DESCRIPTION

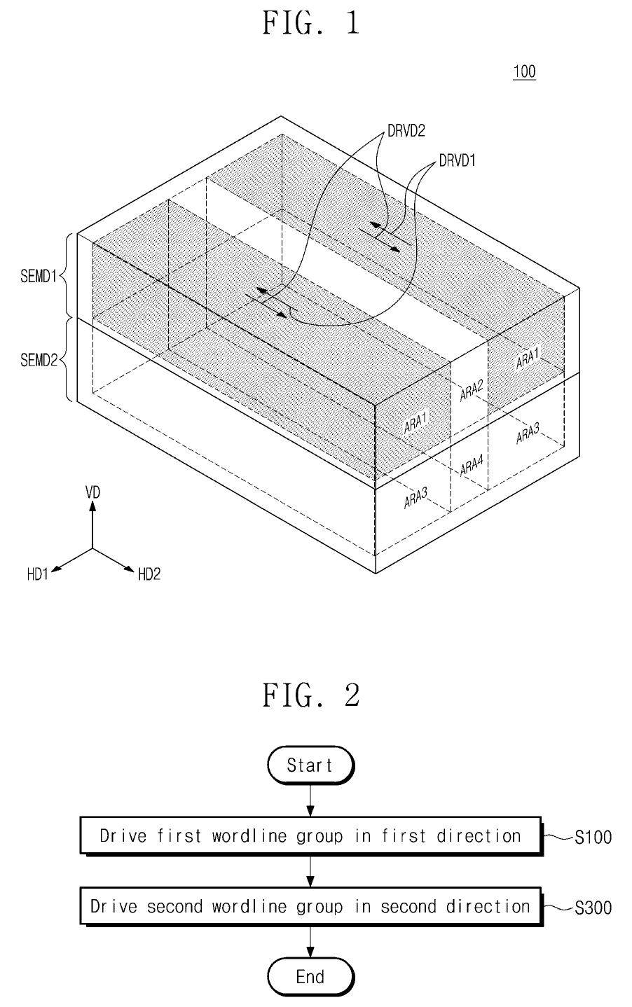

FIG. 1 is a perspective view illustrating an example of a semiconductor memory device.

In FIG. 1, directions VD, HD1, and HD2 perpendicular to each other are shown. Hereinafter, the directions VD, HD1, and HD2 may be uniformly used. The direction VD may be referred to as a ‘vertical direction’, and each of the directions HD1 and HD2 may be referred to a ‘horizontal direction’.

Referring to FIG. 1, a semiconductor memory device 100 may include a first semiconductor die SEMD1 and a second semiconductor die SEMD2. The first semiconductor die SEMD1 and the second semiconductor die SEMD2 may be stacked in the vertical direction to each other. The semiconductor memory device 100 may be, for example dynamic random access memory (DRAM), double data rate 4 (DDR4), synchronous DRAM (SDRAM), low power DDR4 (LPDDR4) SDRAM, LPDDR5 SDRAM, graphics double data rate 5 (GDDR5) SDRAM, GDDR6 SDRAM, high bandwidth memory 2 (HBM2), HBM2E, or HBM3, but the memory type is not limited thereto.

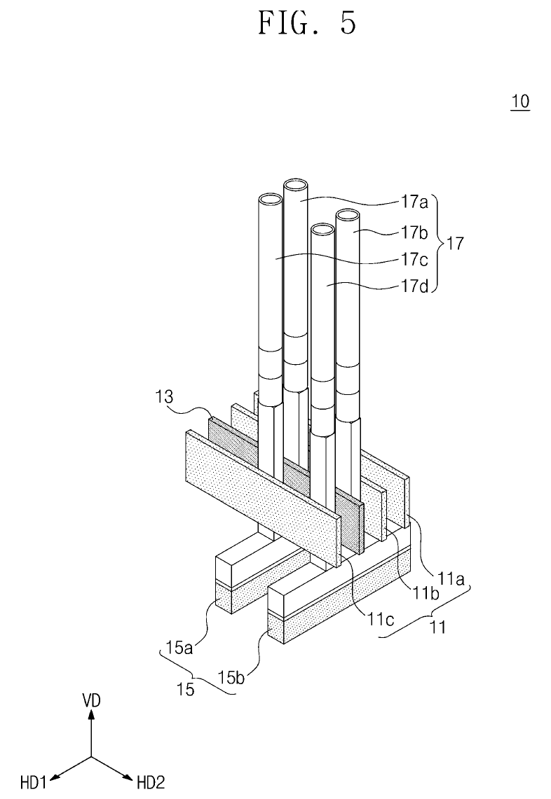

In some implementations, the semiconductor memory device 100 may have memory cells in which a vertical channel array transistor (VCAT) structure using vertical channel transistors is employed, and may have a cell on periphery (COP) structure in which peripheral circuits are disposed below the memory cells. By having such a VCAT structure and a COP structure, the semiconductor memory device 100 can increase storage capacity, increase integration density, improve space utilization, and reduce production costs. However, the scope of the present disclosure is not limited to the VCAT structure and COP structure. The semiconductor memory device 100 may have a peripheral on cell (POC) structure. The VCAT structure will be described below with reference to FIG. 5.

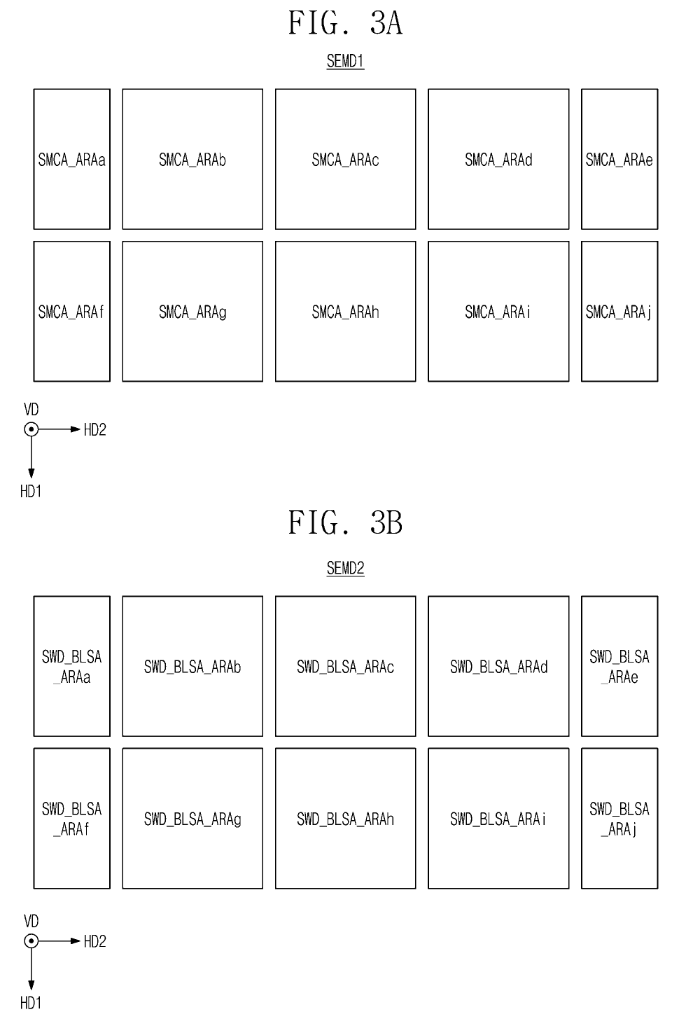

Semiconductor memory device 100 may include a memory cell array and peripheral circuits associated with the memory cell array. For example, the memory cell array may include a plurality of sub-memory cell arrays, each of which may include a plurality of memory blocks (or a plurality of mats MATs), each of which may include a plurality of memory cells. For example, the peripheral circuits may include multiple circuits for writing, reading, managing, etc., data associated with the memory cells. Areas in which a plurality of sub-memory cell arrays and peripheral circuits are disposed will be described below with reference to FIGS. 3A and 3B.

The semiconductor memory device 100 may include internal areas ARA1, ARA2, ARA3, and ARA4. Each of the areas ARA1 and ARA2 may be an area inside the first semiconductor die SEMD1, and each of areas ARA3 and ARA4 may be an area within the second semiconductor die SEMD2.

Each of the areas ARA1 and ARA3 may be one or more, as shown in FIG. 1. The area ARA1 may include the memory cell array, the plurality of sub-memory cell arrays, the plurality of memory blocks, and the plurality of memory cells, and may further include a plurality of wordlines, a plurality of bitlines, and a plurality of backgatelines, that are electrically connected to the plurality of memory cells. The area ARA3 may include a plurality of sub-wordline drivers electrically connected to the plurality of wordlines and a plurality of bitline sense amplifiers connected to the plurality of bitlines, and may further include a row decoder controlling the plurality of sub-wordline drivers and a column decoder controlling the plurality the bitline sense amplifiers.

In some implementations, the first semiconductor die SEMD1 may include a first wordline group and a second wordline group, and may include a first backgateline disposed between the first wordline group and the second wordline group. For example, the plurality of wordlines may be sequentially disposed along a horizontal direction, and each of the first wordline group and the second wordline group may include wordlines that are adjacent to each other and multiples of two.

Hereinafter, that a certain sub-wordline driver group (or a certain sub-wordline driver included in the sub-wordline driver group) drives a specific wordline group (or a specific wordline included in the specific wordline group) in a specific direction implies that a driving signal applied to one end of the specific wordline by the certain sub-wordline drivers propagates to the other end. For example, when a specific wordline is driven by a certain sub-wordline driver, a current flowing in the wordline may propagate in accordance with the specific direction.

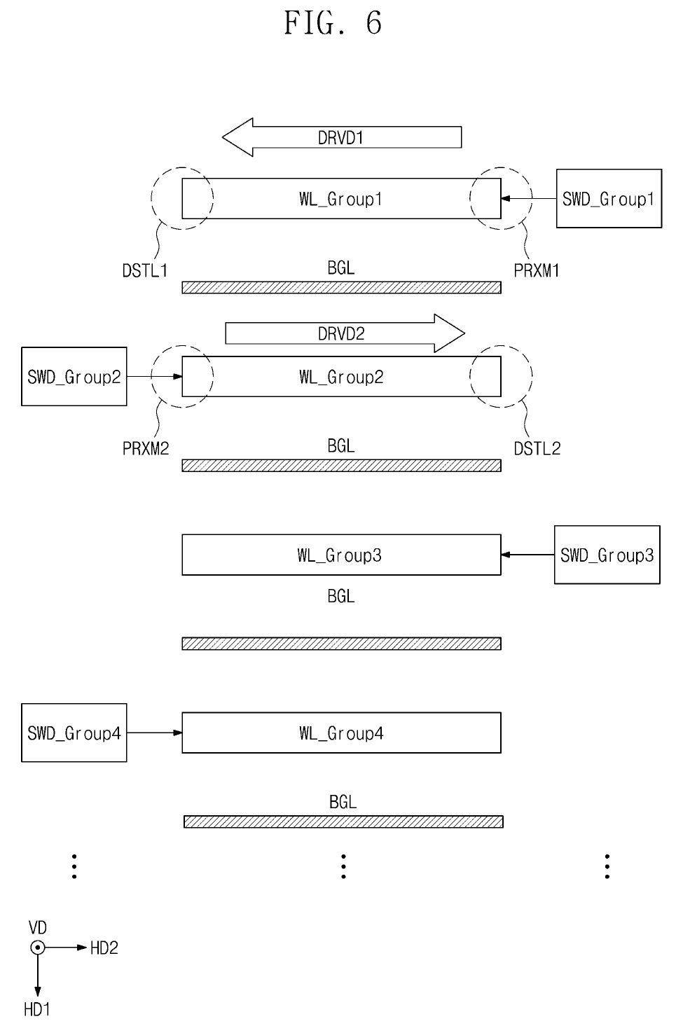

In some implementations, the second semiconductor die SEMD2 may include a first sub-wordline driver group and a second sub-wordline driver group, the first sub-wordline driver group may drive the wordlines included in the first wordline group in a first direction (e.g., DRVD1) that is an extension direction of the wordlines, and the second sub-wordline driver group may drive the wordlines included in the second wordline group in a second direction (e. g., DRVD2) that is opposite to the first direction. This configuration is shown, for example, in FIG. 6. In this case, wordlines included in each wordline group may be sequentially activated one by one. For example, each of the first and second sub-wordline driver groups may include sub-wordline drivers that are adjacent to each other and multiples of two.

In some implementations, the plurality of wordlines may be sequentially disposed along a direction +HD1, and may extend in a direction (e.g., −HD2), in this case, the first direction may be −HD2, and the second direction may be +HD2, but the scope of the present disclosure is not limited thereto. In some implementations, the plurality of wordlines may be sequentially disposed along a direction +HD2 and may extend in a direction (e.g., a VD or −VD direction), in this case the first direction may be +VD and the second direction may be −VD. Therefore, in some implementations, the first direction may be one of the vertical direction and the horizontal direction, and may be perpendicular to the extension direction of the bitline. The second direction may be parallel to the first direction.

Hereinafter, for convenience of description, it is assumed that the plurality of wordlines extend in the direction −HD2. For example, the first sub-wordline driver group may drive wordlines included in the first wordline group in a direction (e.g., −HD2), and the second sub-wordline driver group may drive wordlines included in the second wordline group in the opposite direction (e. g., +HD2), but the scope of the present disclosure is not limited thereto.

In some implementations, the first semiconductor die SEMD1 may further include a third wordline group and a second backgateline disposed between the second wordline group and the third wordline group, and the second semiconductor die SEMD2 may further include a second sub-wordline driver group that drives the third wordline groups in the first direction. The first to third sub-wordline driver groups may be disposed in a zigzag manner along a third direction (e.g., +HD1) perpendicular to the first direction in a horizontal direction.

In some implementations, the first semiconductor die SEMD1 may include odd-numbered wordline groups and even-numbered wordlines groups, and may include a plurality of backgatelines disposed one by one between one of the odd-numbered words line groups and one of the even-numbered words lines groups. For example, the plurality of wordlines may be sequentially disposed along a horizontal direction, each of the odd-numbered wordline groups may include wordlines that are adjacent to each other and multiples of two, and each of the even-numbered wordline groups may include wordlines that are adjacent to each other and multiples of two.

In some implementations, the second semiconductor die SEMD2 may include odd-numbered sub-wordline driver groups and even-numbered sub-wordline driver groups, and the odd-numbered sub-wordline driver group may drive the odd-numbered wordline groups in the first direction, and the even-numbered sub-wordline driver groups may drive the even-numbered wordline groups in the second direction. The odd-numbered and even-numbered sub-wordline driver groups may be disposed in a zigzag manner along the third direction. A manner in which sub-wordline driver groups drive wordline groups will be described below with reference to FIGS. 6, 7, 8, 9, 10, 11A, 11B, 12A, 12B, 13A, 13B, and the like.

With such a configuration, in some implementations, the semiconductor memory device may have a VCAT structure and a COP structure, and may drive wordline groups obtained by dividing wordlines by sub-wordline driver groups obtained by dividing sub-wordline drivers. Each of the sub-wordline driver groups may include sub-wordline drivers that are multiples of two, each of the wordline groups may include wordlines that are multiples of two, and when one of the sub-wordline driver groups drives one of the wordline group in the first direction, another sub-wordline driver group adjacent to the sub-wordline driver group driving in the first direction may drive the other one of the wordline groups in the second direction. A backgateline disposed between different wordline groups can reduce coupling noise between wordlines disposed in different wordline groups, thereby improving refresh characteristics of the semiconductor memory device. For example, this and other configurations described herein can exploit the recognition that coupling noise is not a major problem in wordlines that are driven in the same direction and that are disposed in the same wordline group.

FIG. 2 is a flowchart illustrating an example of a method of operating a semiconductor memory device, e.g., the semiconductor memory device of FIG. 1.

Referring to FIGS. 1 and 2, a first wordline group may be driven in a first direction along an extension direction of wordlines by a first sub-wordline driver group (S100).

The second sub-wordline driver group may drive a second wordline group in the second direction opposite to the first direction (S300).

In some implementations, each of the first wordline group and the second wordline group includes wordlines that are adjacent to each other and multiples of two, and a first backgateline may be disposed between the first wordline group and the second wordline group.

In some implementations, a third wordline group may be driven in the first direction by a third sub-wordline driver group. The third wordline group may include wordlines that are adjacent to each other and multiples of two, and a second backgateline may be disposed between the second wordline group and the third wordline group.

In some implementations, the first to third sub-wordline driver groups may be disposed in a zigzag manner along a third direction perpendicular to the first direction in a horizontal direction.

FIGS. 3A and 3B are diagrams illustrating examples of the semiconductor dies of FIG. 1.

Referring to FIG. 1 and FIG. 3A, the first semiconductor die SEMD1 may include a plurality of sub-memory cell array areas SMCA_ARAa, SMCA_ARAb, SMCA_ARAc, SMCA_ARAd, SMCA_ARAe, SMCA_ARAf, SMCA_ARAg, SMCA_ARAh, SMCA_ARAi, and SMCA_ARAj. The areas SMCA_ARAa to SMCA_ARAe may be disposed in a first row, and the areas SMCA_ ARAf to SMCA_ ARAj may be disposed in a second row. Each of the areas SMCA_ARAa to SMCA_ARAj may include a plurality of memory blocks, and each of the plurality of memory blocks may include a plurality of memory cells coupled to a plurality of wordlines, a plurality of bitlines, and a plurality of backgatelines. For example, the plurality of wordlines may be sequentially disposed along the direction +HD1 and may extend in the direction (e.g., −HD2), but the arrangement is not limited thereto.

Referring to FIG. 1 and FIG. 3B, the second semiconductor die SEMD2 may include a plurality of sub-wordline driver and bitline sense amplifier areas SWD_BLSA_ARAa, SWD_BLSA_ARAb, SWD_BLSA_ARAc, SWD_BLSA_ARAd, SWD_BLSA_ARAe, SWD_BLSA_ARAf, SWD_ BLSA_ARAg, SWD_BLSA_ARAh, SWD_BLSA_ARAi, and SWD_BLSA_ARAj. The areas SWD_BLSA_ARAa to SWD_BLSA_ARAe may be disposed in a first row, and the areas SWD_BLSA_ARAf to SWD_BLSA_ARAj may be disposed in a second row. For example, sub-wordline drivers and bitline sense amplifiers disposed in the area SWD_BLSA_ARAa may drive or sense memory cells disposed in the area SMCA_ARAa, sub-wordline drivers and bitline sense amplifiers disposed in the area SWD_BLSA_ARAb may drive or sense memory cells disposed of in the area SMCA_ARAb, and sub-wordline drivers and bitline sense amplifiers disposed in the area SWD_BLSA_ARAc may drive or sense memory cells disposed in the area SMCA_ARAc. In a similar manner, the sub-wordline drivers and the bitline sense amplifiers disposed in the areas SWD_BLSA_ARAd to SWD_BLSA_ARAj may respectively drive or sense the memory cells disposed in the areas SMCA_ARAd to SMCA_ARAj.

In FIGS. 3A and 3B, the sub-memory cell array areas SMCA_ARAa to SMCA_ARAj and the sub-wordline driver and bitline sense amplifier areas SWD_BLSA_ARAa to SWD_BLSA_ARAj have a two-row, five-column arrangement, but this is merely as an example. The sub-memory cell array areas, and the sub-wordline driver and bitline sense amplifier areas may be disposed in fewer or more rows and/or columns.

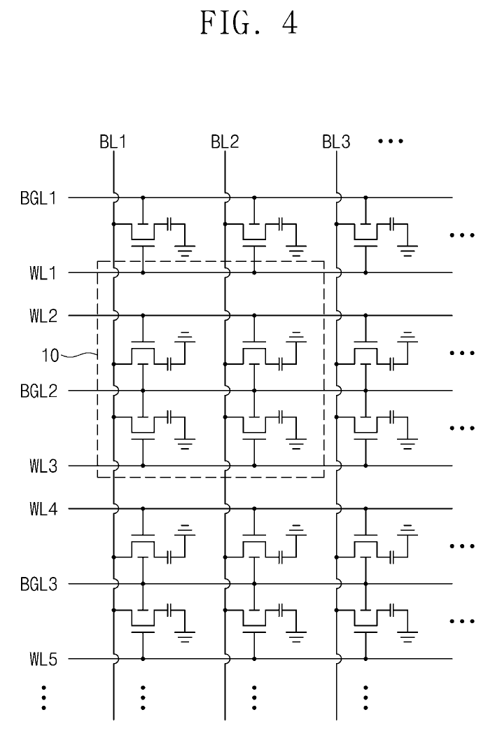

FIG. 4 is a circuit diagram illustrating an example of memory cells, e.g., of the semiconductor memory device of FIG. 1. FIG. 5 is a perspective view illustrating an example of a vertical channel array transistor (VCAT) structure.

In FIG. 4, memory cells are shown, and in FIG. 5, a portion 10 of the memory cells of FIG. 4 are shown.

Referring to FIGS. 1 and 4, a total of 15 memory cells may be connected to five wordlines WL1, WL2, WL3, WL4, and WL5, three bitlines BL1, BL2, and BL3, and three backgatelines BGL1, BGL2, and BGL3.

A transistor of a corresponding memory cell may be turned on by each of the wordlines WL1 to WL5, and data may be written to or read from the corresponding memory cell by each of the bitlines BL1 to BL3.

Each of the backgatelines BGL1 to BGL3 may improve the performance and stability of a transistor of a memory cell. For example, the backgateline may adjust the threshold voltage of the transistor of the corresponding memory cell to improve the operating characteristics of the transistor, reducing the leakage current, and affecting the channel region to improve the current driving capability of the transistor to increase the write or read speed and control the floating body effect.

Referring to FIGS. 1, 4, and 5, a portion 10 of memory cells may include wordlines 11a, 11b, and 11c (collectively referred to as wordlines 11), bitlines 15a, and 15b (collectively referred to as bitlines 15), backgateline 13, and capacitors 17a, 17b, 17c, and 17d (collectively referred to as capacitors 17).

In some implementations, bitlines 15 may extend in one direction (e.g., −HD1), and wordlines 11 may extend in another direction (e.g., −HD2). The backgateline 13 may extend in a horizontal direction (e.g., −HD2), and the capacitors 17 may extend in a vertical direction (e.g., VD). For example, channels of transistors of memory cells may be formed in the vertical direction between the wordlines 11 and the backgateline 13.

In memory cells having a VCAT structure, a capacitance component between adjacent wordlines may increase relative to some other memory cell structure (e.g., a buried channel array transistor (BCAT) structure). This may be due to the insertion of backgatelines to control floating body effects that may occur as vertical channels are formed, resulting in a decrease in dimension between wordlines and an increase in dielectric ratio between wordlines. When coupling noise is caused to an adjacent wordline that is not selected by the selected wordline, a probability that data is lost may be increased.

FIG. 6 is a diagram illustrating an example of a configuration in which sub-wordline driver groups drive wordline groups in a semiconductor memory device, e.g., the semiconductor memory device of FIG. 1.

Referring to FIGS. 1 and 6, the first semiconductor die SEMD1 may include wordline groups WL_Group1, WL_Group2, WL_Group3, WL_Group4, etc., and backgatelines BGLs disposed between the wordline groups, and the second semiconductor die SEMD2 may include sub-wordline driver groups SWD_Group1, SWD_Group2, SWD_Group3, SWD_Group4, etc.

The sub-wordline driver group SWD_Group1 may drive the wordline group WL_Group1 (or wordlines included therein) in a first direction (e.g., DRVD1) along an extension direction of the wordlines, and the sub-wordline driver group SWD_Group2 may drive the wordline group WL_Group2 (or wordlines included therein) in a second direction (e. g., DRVD2) opposite to the first direction. The sub-wordline driver group SWD_Group3 may drive the wordline group WL_Group3 (or wordlines included therein) in the first direction, and the sub-wordline driver group SWD_Group4 may drive the wordline group WL_Group4 (or wordlines included therein) in the second direction. In this case, in some implementations, that the sub-wordline driver group drives the wordline group can include that one sub-wordline driver included in a specific sub-wordline driver group sequentially activates one wordline included in a specific wordline group.

For example, when the sub-wordline driver group SWD_Group1 drives the wordline group WL_Group1, a voltage fluctuation may first occur in a proximal area PRXM1 of the wordline group WL_Group1 and then the voltage fluctuation may occur in a distal area DSTL1. While the sub-wordline driver group SWD_Group1 drives the wordline group WL_Group1, the remaining sub-wordline driver groups SWD_Group2, SWD_Group3, and SWD_Group4 may not drive the wordline groups WL_Group2, WL_Group3, and WL_Group4, and, for example, voltage fluctuations by the sub-wordline driver group SWD_Group2 may not occur in the proximal region PRXM2 and the distal region DSTL2 of the wordline group WL_Group2. Therefore, the voltage fluctuation occurring in the proximal region PRXM1 of the wordline group WL_Group1 may affect the distal region DSTL2 of the wordline group WL_Group2, which may act as coupling noise in the wordline group WL_Group2 according to the voltage fluctuation of the wordline groups WL_Group1. However, in some implementations described herein, backgatelines disposed between wordline groups can provide a useful shielding effect. Therefore, wordlines disposed between backgatelines in the semiconductor memory device may be grouped as one wordline group, and sub-wordline drivers for driving these wordlines may be grouped as one sub-wordline driver group to drive the wordline group in the same direction.

In some implementations (e.g., in configurations as shown in FIG. 4), since the wordlines disposed between the backgatelines may be grouped as one wordline group, the number of wordlines included in one wordline group may be multiples of two, and the number of sub-wordline drivers included in a sub-wordline driver group for driving the wordlines included in the one wordline group may also be multiples of two.

In some implementations, the number of wordlines included in the wordline group WL_Group1 may be equal to the number of wordlines included in the wordline group WL_Group2.

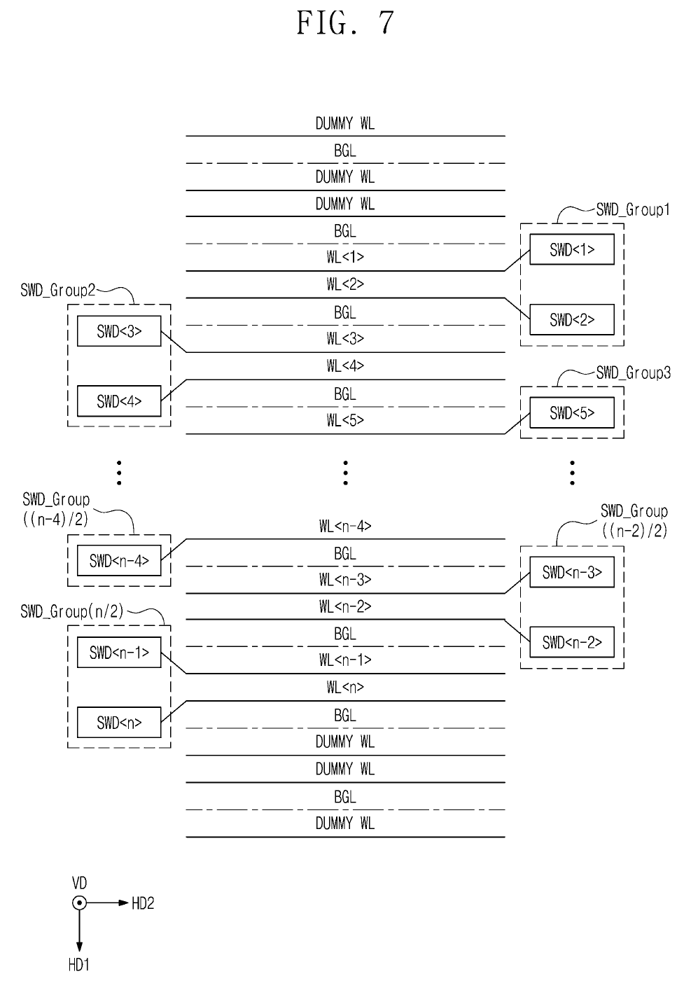

FIGS. 7, 8, and 9 are diagrams illustrating examples of configurations in which sub-wordline driver groups drive wordline groups, e.g., corresponding to the configuration of FIG. 6.

In FIG. 7, sub-wordline drivers SWD<1>, SWD<2>, SWD<3>, SWD<4>, SWD<5>, ... SWD<n-4>, SWD<n-3>, SWD<n-2>, SWD<n-1>, and SWD<n> are shown that drive wordlines WL<1>, WL<2>, WL<3>, WL<4>, WL<5>, …, WL<n-4>, WL<n-3>, WL<n-2>, WL<n-1>, and WL<n>. Backgatelines BGLs may be disposed between the wordlines, one for each pair of the two wordlines as shown in FIG. 7, and dummy wordlines DUMMY WL for increasing the stability of the semiconductor memory device may be further disposed.

Referring to FIGS. 6 and 7, two wordlines may be grouped as one wordline group, and two sub-wordline drivers for driving these wordlines may be grouped as one sub-wordline driver group.

For example, the sub-wordline drivers SWD<1> and SWD<2> may be grouped into a sub-wordline driver group SWD_Group1, and the sub-wordline drivers SWD<3> and SWD<4> may be grouped as a sub-wordline driver group SWD_Group2. In a similar manner, the sub-wordline drivers SWD<5>, …., SWD<n−4>, SWD<n−3>, SWD<n−2>, SWD<n−1>, and SWD<n> may be grouped as sub-wordline driver groups SWD_Group3, ..., SWD_Group((n−4)/2), SWD_Group((n−2)/2), and SWD_Group(n/2), respectively.

In some implementations, the sub-wordline driver group SWD_Group1 may drive the wordline group including the wordlines WL<1> and WL<2> in the first direction (e.g., −HD2). For example, the sub-wordline driver SWD<1> may drive the wordline WL<1> in the first direction, and the sub-wordline driver SWD<2> may drive the wordline WL<2> in the first direction.

In some implementations, the sub-wordline driver group SWD_Group2 may drive the wordline group including the wordlines WL<3> and WL<4> in the second direction (e.g., +HD2). For example, the sub-wordline driver SWD<3> may drive the wordline WL<3> in the second direction, and the sub-wordline driver SWD<4> may drive the wordline WL<4> in the second direction.

In a similar manner, the sub-wordline driver groups SWD_Group3, …., SWD_Group((n−4)/2), SWD_Group((n−2)/2), and SWD_Group(n/2) may drive the corresponding wordline groups in the first direction or the second direction.

In some implementations, the wordlines WL<1> to WL<n> may be sequentially driven one by one. For example, while the wordline WL<1> is activated, the remaining wordlines WL<2> to WL<n> may be deactivated.

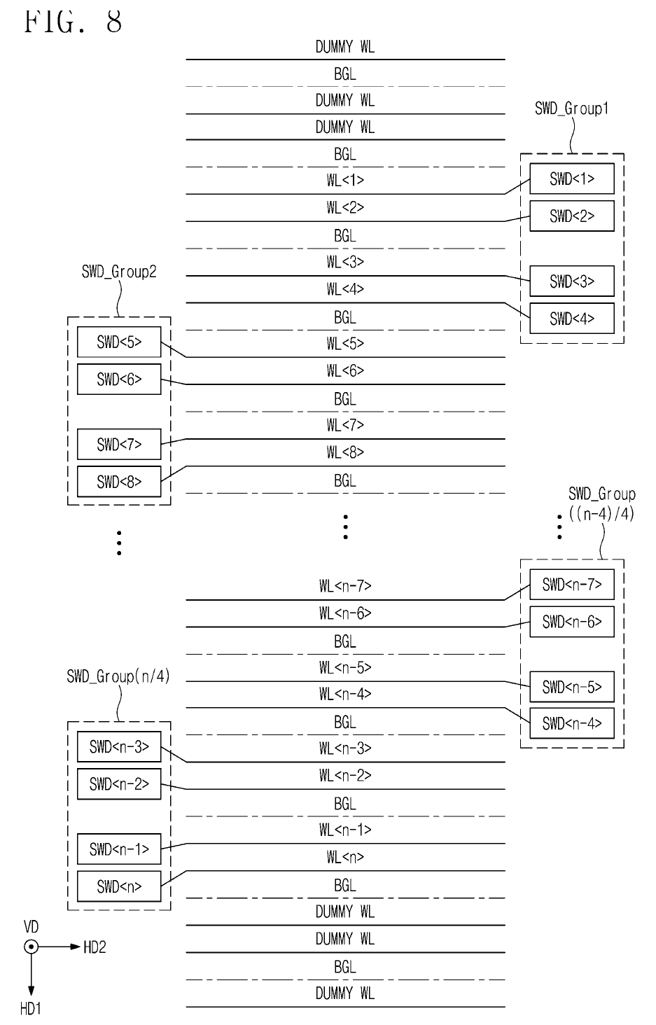

Referring to FIGS. 6 and 8, in some implementations, four wordlines may be grouped as one wordline group, and four sub-wordline drivers for driving these wordlines may be grouped as one sub-wordline driver group.

For example, the sub-wordline drivers SWD<1> to SWD<4> may be grouped as a sub-wordline driver group SWD_Group1, and the sub-wordline drivers SWD<5> to SWD<8> may be grouped as a sub-wordline driver group SWD_Group2. In a similar manner, the sub-wordline drivers SWD<n−7> to SWD<n> may be grouped as sub-wordline driver groups SWD_Group((n−4)/4) and SWD_Group(n/4), respectively.

In some implementations, the sub-wordline driver group SWD_Group1 may drive the wordline group including the wordlines WL<1> to WL<4> in the first direction (e.g., −HD2). For example, the sub-wordline driver SWD<1> may drive the wordline WL<1> in the first direction, and the sub-wordline driver SWD<2> may drive the wordline WL<2> in the first direction. The sub-wordline driver SWD<3> may drive the wordline WL<3> in the first direction, and the sub-wordline driver SWD<4> may drive the wordline WL<4> in the first direction.

In some implementations, the sub-wordline driver group SWD_Group2 may drive the wordline group including the wordlines WL<5> to WL<8> in the second direction (e.g., +HD2). For example, the sub-wordline driver SWD<5> may drive the wordline WL<5> in the second direction, and the sub-wordline driver SWD<6> may drive the wordline WL<6> in the second direction. The sub-wordline driver SWD<7> may drive the wordline WL<7> in the second direction, and the sub-wordline driver SWD<8> may drive the wordline WL<8> in the second direction.

In a similar manner, the sub-wordline driver groups SWD_Group((n−4)/4) and SWD_Group(n/4) may drive the corresponding wordline groups in the first direction or the second direction.

In some implementations, the wordlines WL<1> to WL<n> may be sequentially driven one by one. For example, while the wordline WL<1> is activated, the remaining wordlines WL<2> to WL<n> may be deactivated.

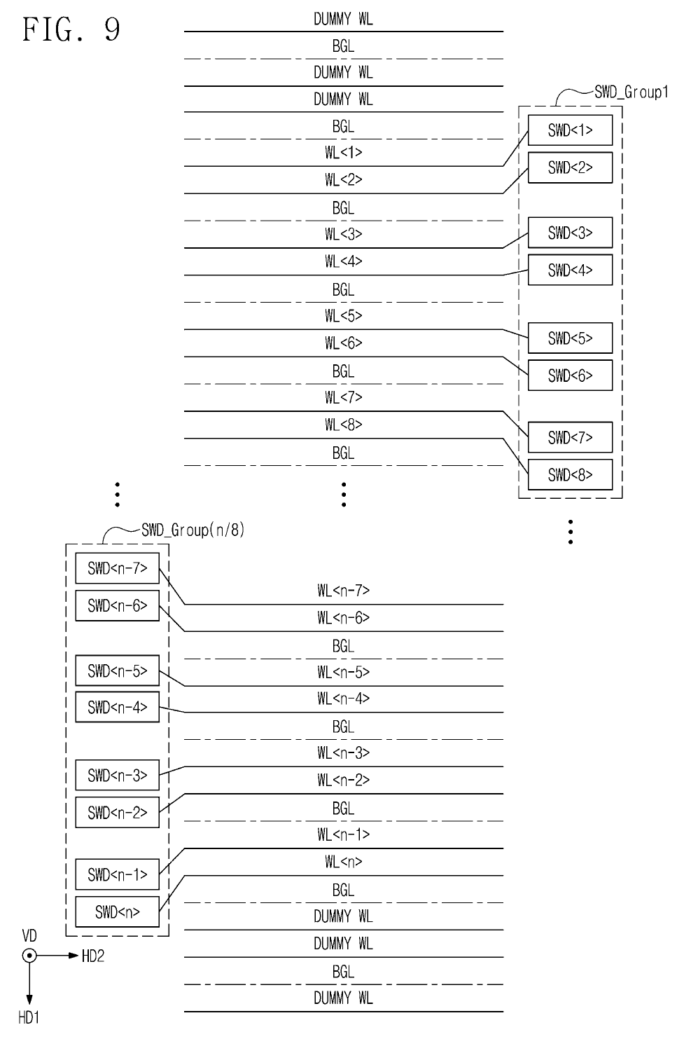

Referring to FIGS. 6 and 9, in some implementations, eight wordlines may be grouped as one wordline group, and eight sub-wordline drivers for driving these wordlines may be grouped as one sub-wordline driver group.

For example, the sub-wordline drivers SWD<1> to SWD<8> may be grouped as a sub-wordline driver group SWD_Group1. In a similar manner, the sub-wordline drivers SWD<n−7> to SWD<n> may be grouped as a sub-wordline driver group SWD_Group(n/8).

In some implementations, the sub-wordline driver group SWD_Group1 may drive the wordline group including the wordlines WL<1> to WL<8> in the first direction (e.g., −HD2). For example, the sub-wordline driver SWD<1> may drive the wordline WL<1> in the first direction, the sub-wordline driver SWD<2> may drive the wordline WL<2> in the first direction, and the sub-wordline driver SWD<3> may drive the wordline WL<3> in the first direction. The remaining sub-wordline drivers SWD<4> to SWD<8> may also drive the wordline WL<3> to WL<8> in the first direction.

In a similar manner, the sub-wordline driver group SWD_Group(n/8) may drive the corresponding wordline group in the second direction.

In some implementations, the wordlines WL<1> to WL<n> may be sequentially driven one by one. For example, while the wordline WL<1> is activated, the remaining wordlines WL<2> to WL<n> may be deactivated.

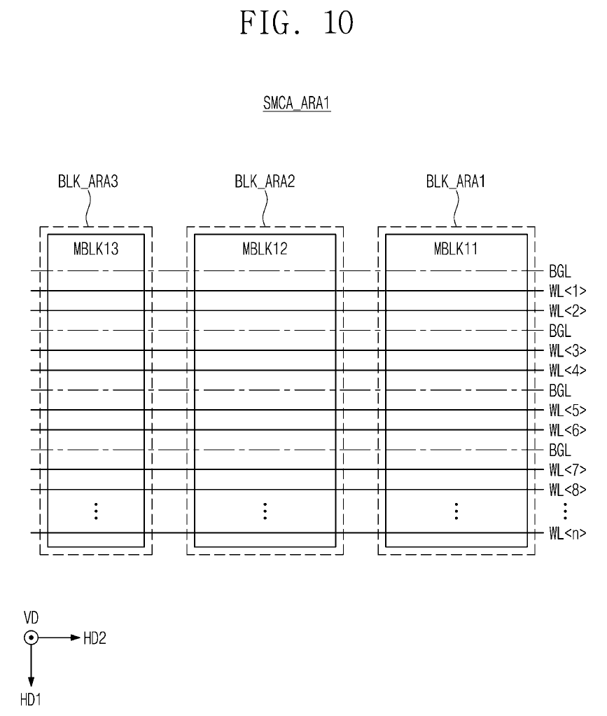

FIG. 10 is a diagram illustrating an example of a sub-memory cell array area, e.g., the sub-memory cell array area of FIG. 3A.

Referring to FIG. 10, a sub-memory cell array area SMCA_ARA1 may correspond to one of the sub-memory cell array areas SMCA_ARAa to SMCA_ARAj shown in FIG. 3A.

The sub-memory cell array area SMCA_ARA1 may include a plurality of memory block areas BLK_ARA1, BLK_ARA2, BLK_ARA3, …. including memory blocks MBLK11, MBLK12, and MBLK13, respectively.

In some implementations, a plurality of wordlines WL<1> to WL<n> and a plurality of backgatelines BGLs may pass through the plurality of memory block areas BLK_ARA1 to BLK_ARA3. For convenience of illustration, bitlines and memory cells are omitted.

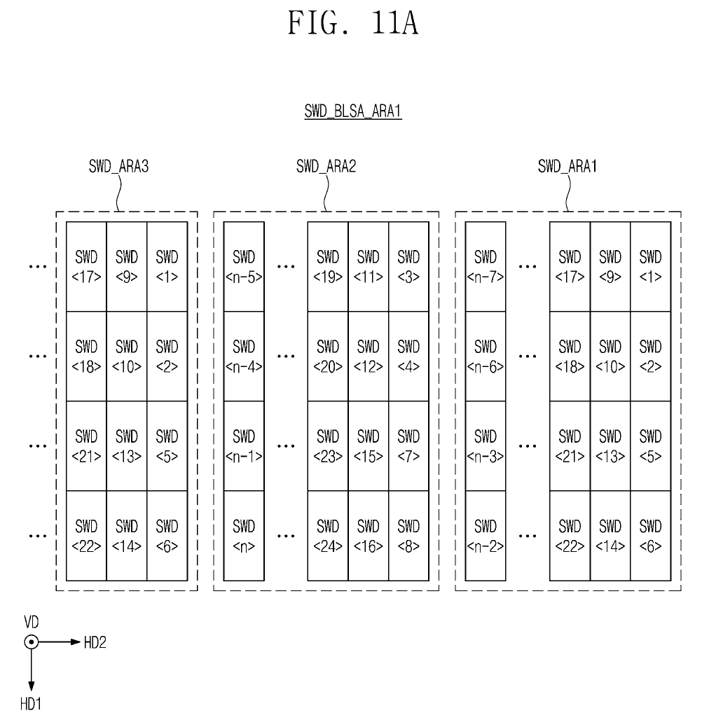

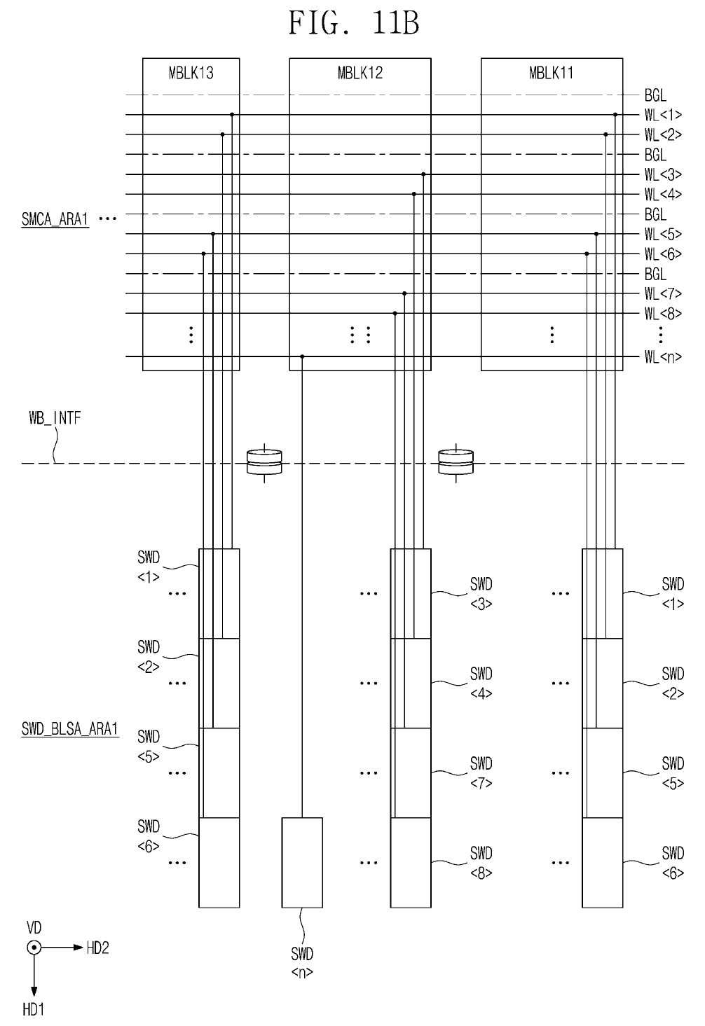

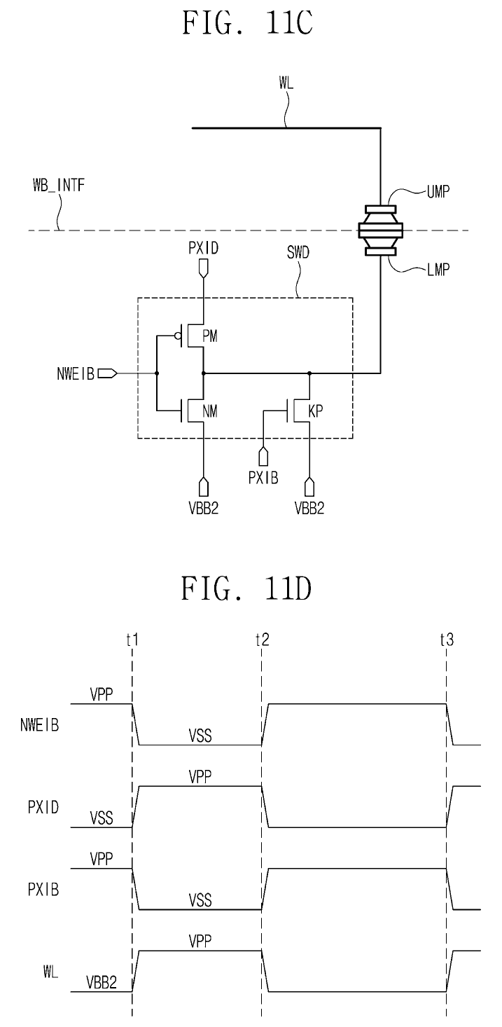

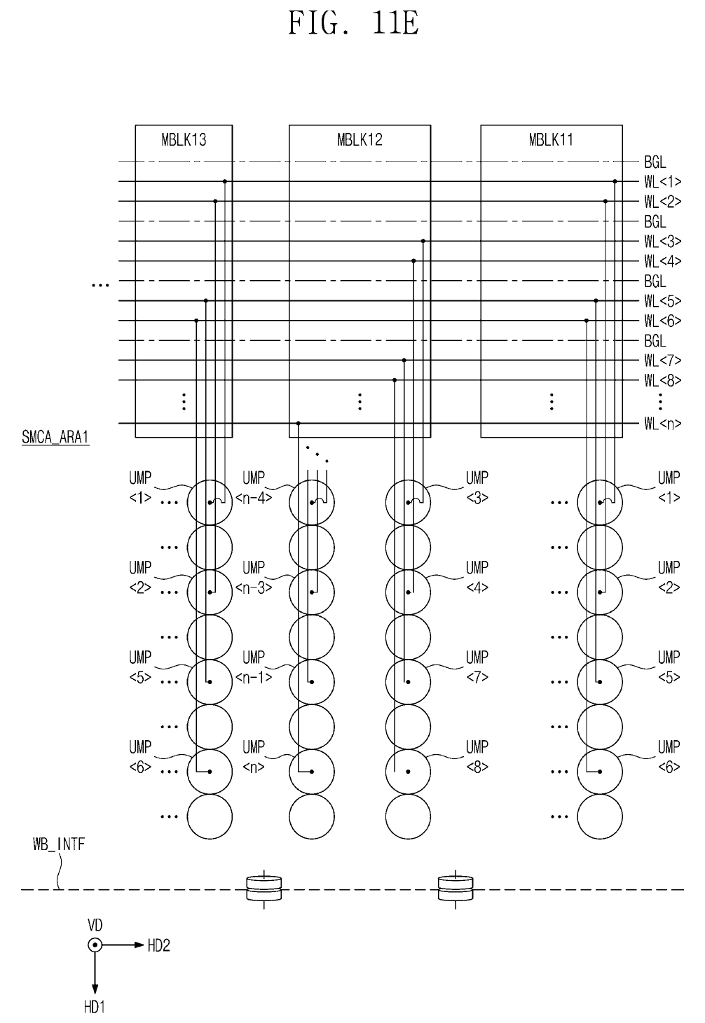

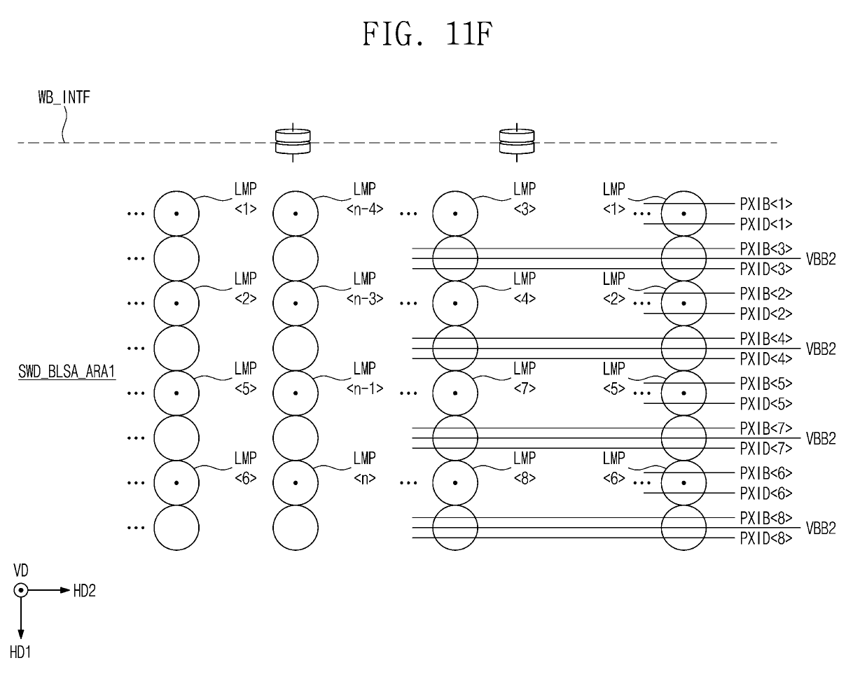

FIG. 11A is a diagram illustrating an example of a sub-wordline driver and bitline sense amplifier area, e.g., the sub-wordline driver and bitline sense amplifier area of FIG. 3B.

Referring to FIG. 11A, the sub-wordline driver and the bitline sense amplifier area SWD_BLSA_ARA1 may correspond to one of the sub-wordline driver and the bitline sense amplifier areas SWD_BLSA_ARAa to SWD_BLSA_ARAj shown in FIG. 3B, and may correspond to the example shown in FIG. 7. Therefore, the sub-wordline drivers SWD<1> and SWD<2> may be grouped as a sub-wordline driver group SWD_Group1, and the sub-wordline driver SWD<3> and SWD<4> may be grouped as a sub-wordline driver group SWD_ Group2. In a similar manner, the sub-wordline drivers SWD<5>, …, SWD<n−4>, SWD<n−3>, SWD<n−2>, SWD<n−1>, and SWD<n> may be grouped as sub-wordline driver groups SWD_Group3, …., SWD_Group((n-4)/2), SWD_Group((n-2)/2), SWD_Group(n/2), respectively.

The sub-wordline driver and the bitline sense amplifier area SWD_BLSA_ARA1 may include a plurality of sub-wordline driver areas SWD_ARA1, SWD_ARA2, SWD_ARA3 …. including the plurality of sub- wordline drivers SWD<1> to SWD<n>. For example, the sub-wordline driver area SWD_ARA1 may be a lower area of the memory block area BLK_ARA1, the sub-wordline driver area SWD_ARA2 may be a lower area of the memory block area BLK_ARA2, and the sub-wordline driver area SWD_ARA3 may be lower area of the memory block area BLK_ARA3.

In some implementations, a sub-wordline driver group or sub-wordline drivers driving a wordline group included in the memory block area BLK_ARA1 in a first direction (e.g., −HD2) may be disposed in the sub-wordline driver area SWD_ARA1, which is a lower area of the memory block area BLK_ARA1. A sub-wordline driver group or sub-wordline drivers driving a wordline group included in the memory block area BLK_ARA2 in a second direction opposite to the first direction may be disposed in the sub-wordline driver area SWD_ARA2, which is a lower area of the memory block area BLK_ARA2. For example, the memory block area BLK_ARA2 may be disposed in the first direction from the memory block area BLK_ARA1, and the sub-wordline driver area SWD_ARA2 may also be disposed in the first direction from the sub-wordline driver area SWD_ ARA1. Therefore, as shown in FIG. 11A, the sub-wordline drivers SWD<1>, SWD<2>, SWD<5>, SWD<6>, SWD<9>, SWD<10>, SWD<13>, SWD<14>, SWD<17>, SWD<18>, SWD<21>, SWD<22>, …., SWD<n−7>, SWD<n−6>, SWD<n−3>, SWD<n−2> may be disposed in the sub-wordline driver area SWD_ARA1, and the sub-wordline drivers SWD<3>, SW D<4>, SWD<7>, SWD<8>, SWD<11>, SWD<12>, SWD<15>, SWD<16>, SWD<19>, SWD<20>, SWD<23>, SWD<24>, …, SWD<n-5>, SWD<n-4>, SWD<n-1>, SWD<n> may be disposed in the sub-wordline driver area SWD_ARA2. The sub-wordline driver area SWD_ARA3 is only partially shown, and areas having the same shape as the sub-wordline driver areas SWD_ARA1 and SWD_ARA2 may be repeated in the direction −HD2.

FIG. 11B is a diagram illustrating an example of a configuration in which the sub-wordline drivers of FIG. 11A drive the wordlines of FIG. 10.

Referring to FIGS. 11A and 11B, the sub-memory cell array area SMCA_ARA1 and the sub-wordline driver and bitline sense amplifier area SWD_BLSA_ARA1 may be electrically connected by a wafer bonding interface WB_INTF. For example, sub-memory cell array area SMCA_ARA1 may include a plurality of upper metal pads disposed at lower portions of memory blocks MBLK11, MBLK12, MBLK13, etc., and the sub-wordline driver and bitline sense amplifier area SWD_BLSA_ARA1 may include a plurality of lower metal pads disposed at lower portions of the plurality of upper metal pads. For example, through the plurality of upper metal pads and the plurality of lower metal pads, a plurality of sub-wordline driver groups may drive the plurality of wordline groups in the first direction or the second direction, as shown in FIG. 11A.

FIG. 11C is a diagram for describing a scheme in which one of the sub-wordline drivers of FIG. 11A and one of the wordlines of FIG. 10 are connected. FIG. 11D is a timing diagram illustrating an example of control signals for controlling the sub-wordline driver of FIG. 11C.

Referring to FIG. 11C, the sub-wordline driver SWD may include a pull-up transistor PM, a pull-down transistor NM, and a keeping transistor KP. The sub-wordline driver SWD may drive the wordline WL through a lower metal pad LMP and an upper metal pad UMP that may configure the wafer bonding interface WB_INTF based on wordline enable signal NWEIB and control signals PXID, PIXB, and VBB2.

In FIG. 11D, voltage levels of the wordline enable signal NWEIB, the control signals PXID and PXIB, and the wordline WL are shown. The voltage levels of the signals shown in FIG. 11D may be associated with a sub-wordline driver that activates the wordline WL.

Referring to FIGS. 11C and 11D, the wordline enable signal NEWIB, and the control signals PXID and PXIB may have one of a voltage level VPP and a voltage level VSS. The voltage level VPP may be a signal level sufficient to turn off the pull-up transistor PM and to turn on the pull-down transistor NM, and the voltage level VSS may be a signal level sufficient to turn on the pull-up transistor PM and to turned off the pull-down transistor NM. The wordline WL may have one of the voltage level VPP and the voltage level VBB2. The voltage level VPP may be a high voltage level sufficient to activate wordline WL, and the voltage level VBB2 may be a low voltage level sufficient to deactivate wordline WL.

The wordline enable signal NWEIB has the voltage level VPP before t1, and may transition to the voltage level VSS at t1, and be maintained at the voltage level VSS until t2. The wordline enable signal NWEIB may transition to the voltage level VPP at t2, and be maintained at the voltage level VPP until t3.

The control signal PXID has the voltage level VSS before t1, and may transition to the voltage level VPP at t1 and be maintained at the voltage level VPP until t2. The control signal PXID may transition to the voltage level VSS at t2 and be maintained at the voltage level VSS until t3. When the control signal PXID has the voltage level VSS, the control signal PXIB may have the voltage level VPP, and when the control signal PXID has the voltage level VPP, the control signal PXIB may have the voltage level VSS.

Before t1, or between t2 and t3, since the wordline enable signal NWEIB has the voltage level VPP and the control signal PXIB has the voltage level VPP, the pull-down transistor NM and the keeping transistor KP are turned on, such that the voltage level of the wordline WL may represent the negative voltage VBB2.

Between t1 and t2, or after t3, since the wordline enable signal NWEIB has the voltage level VSS and the control signal PXIB has a voltage level VSS, the pull-up transistor PM is turned on, such that the voltage level of the wordline WL may represent the voltage level VPP, which is the voltage level of a control signal PXID.

Between t1 and t2, the wordline WL may be activated. Before t1, or between t2 and t3, the wordline WL may be deactivated. For example, between t1 and t2 may correspond to an activation period of the wordline WL, and between t2 and t3 may correspond to a deactivation period of the wordline WL.

FIGS. 11E and 11F are diagrams for describing upper metal pads and lower metal pads for connecting the sub-wordline drivers of FIG. 11A and the wordlines of FIG. 10.

Referring to FIGS. 10, 11A, 11B, 11E, and 11F, the sub-wordline driver SWD<1> may be electrically connected to the wordline WL<1> through a lower metal pattern LMP<1> and an upper metal pattern UMP<1>. The sub-wordline driver SWD<2> may be electrically connected to the wordline WL<2> through a lower metal pattern LMP<2> and an upper metal pattern UMP<2>. The sub-wordline driver SWD<5> may be electrically connected to the wordline WL<5> through a lower metal pattern LMP<5> and an upper metal pattern UMP<5>. The sub-wordline driver SWD<6> may be electrically connected to the wordline WL<6> through a lower metal pattern LMP<6> and an upper metal pattern UMP<6>.

The sub-wordline driver SWD<3> may be electrically connected to the wordline WL<3> through a lower metal pattern LMP<3> and an upper metal pattern UMP<3>. The sub-wordline driver SWD<4> may be electrically connected to the wordline WL<4> through a lower metal pattern LMP<4> and an upper metal pattern UMP<4>. The sub-wordline driver SWD<7> may be electrically connected to the wordline WL<7> through a lower metal pattern LMP<7> and an upper metal pattern UMP<7>. The sub-wordline driver SWD<8> may be electrically connected to the wordline WL<8> through a lower metal pattern LMP<8> and an upper metal pattern UMP<8>.

The sub-wordline driver SWD<n> may be electrically connected with the wordline WL<n> through a lower metal pattern LMP<n> and an upper metal pattern UMP<n>, and the remaining sub-wordline drivers may also be electrically connected with corresponding wordlines through the lower metal patterns and the upper metal patterns in a similar manner.

In some implementations, metal lines for providing the control signals PXIB, PXID, and VBB2 described above with reference to FIG. 11C to corresponding sub-wordline drivers may be disposed at lower portions of the lower metal patterns as shown in FIG. 11F. For example, metal lines for providing control signals PXIB<1>, PXID<1> may be disposed at a lower portion of the lower metal pattern LMP<1>, and metal lines for providing other control signals PXIB<2>, PXID<2>, PXIB<3>, PXID<3>, PXIB<4>, PXID<4>, PXIB<5>, PXID<5>, PXIB<6>, PXID<6>, PXIB<7>, PXID<7>, PXIB<8>, PXID<8>, VBB2 may be disposed at lower portions of corresponding lower metal pattern in a similar manner.

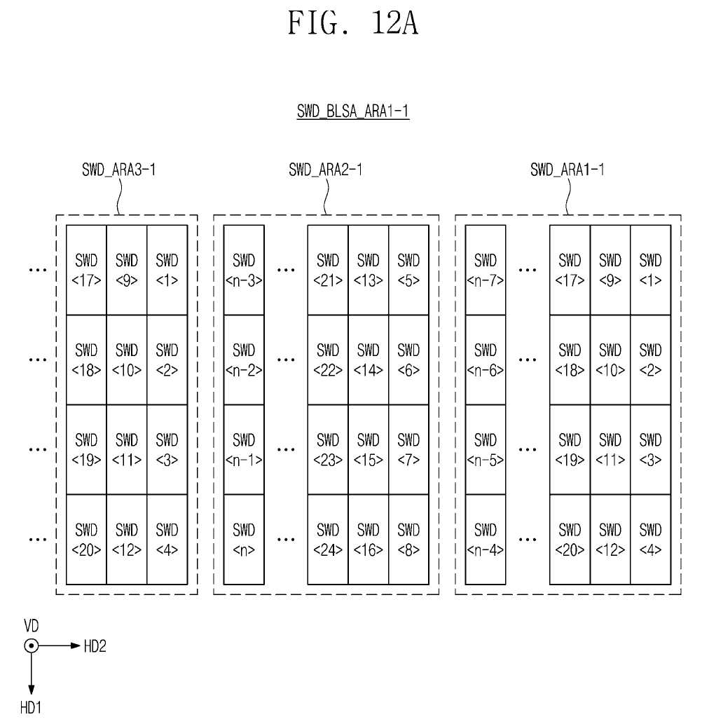

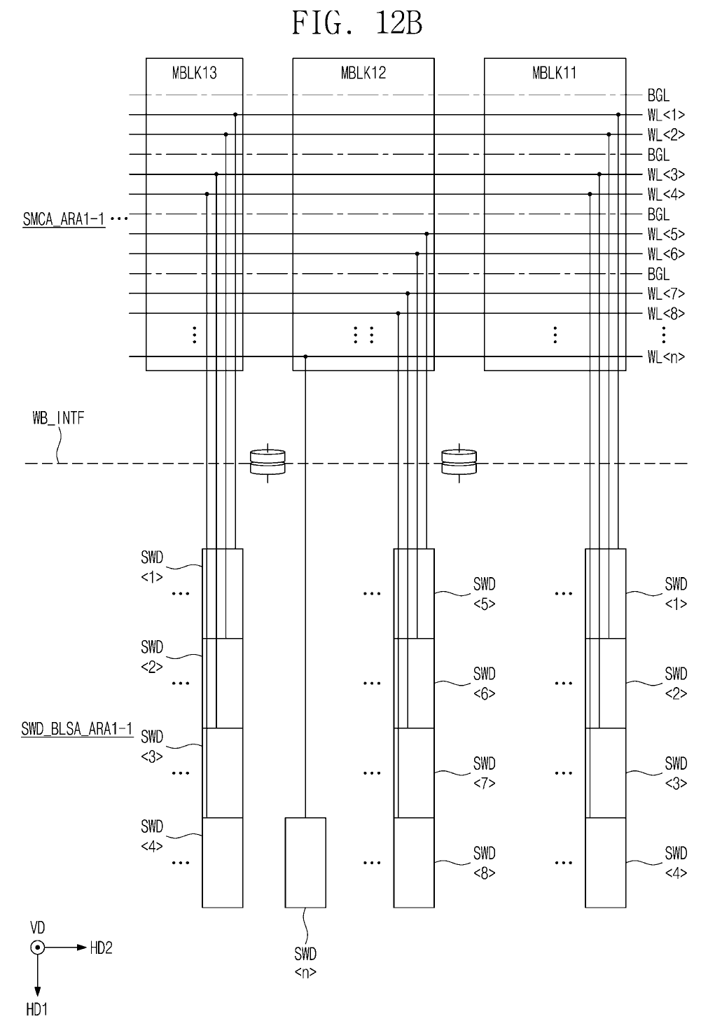

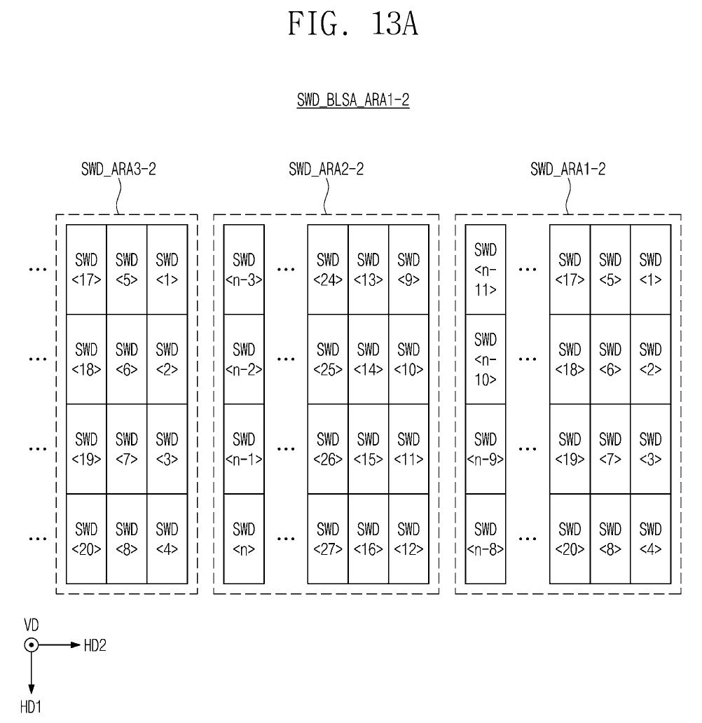

FIG. 12A is a diagram illustrating an example of a sub-wordline driver and bitline sense amplifier area, e.g., the sub-wordline driver and bitline sense amplifier area of FIG. 3B.

Referring to FIG. 12A, the sub-wordline driver and the bitline sense amplifier region SWD_BLSA_ARA1-1 may correspond to one of the sub-wordline driver and bitline sense amplifier areas SWD_BLSA_ARAa to SWD_BLSA_ARAj shown in FIG. 3B, and may correspond to the example shown in FIG. 8. Accordingly, the sub-wordline drivers SWD<1> to SWD<4> may be grouped as the sub-wordline driver group SWD_Group1, and the sub-wordline drivers SWD<5> to SWD<8> may be grouped as the sub-wordline driver group SWD_Group2. In a similar manner, the sub-wordline drivers SWD<n-7> to SWD<n-4> may be grouped as sub-wordline driver groups SWD_Group((n-4)/4), and the sub-wordline drivers SWD<n-3> to SWD<n> may be grouped as the sub-wordline driver group SWD_Group(n/4). The example of FIG. 12A differs from the example shown in FIG. 11A only in the connection relationship between the sub-wordline driver groups and the corresponding wordlines, and thus redundant description will be omitted.

As shown in FIG. 12A, the sub-wordline drivers SWD<1>, SWD<2>, SWD<3>, SWD<4>, SWD<9>, SWD<10>, SWD<11>, SWD<12>, SWD<17>, SWD<18>, SWD<19>, SWD<20>, …., SWD<n−7>, SWD<n−6>, SWD<n−5>, SWD<n−4> may be disposed in a sub-wordline driver area SWD_ARA1-1, and the sub-wordline drivers SWD<5>, SWD<6>, SWD<7>, SWD<8>, SWD<13>, SWD<14>, SWD<15>, SWD<16>, SWD<21>, SWD<22>, SWD<23>, SWD<24>, ..., SWD<n−3>, SWD<n−2>, SWD<n−1>, SWD<n> may be disposed in a sub-wordline driver area SWD_ARA2-1. The sub-wordline driver region SWD_ARA3-1 is only partially illustrated, and areas having the same shape as the sub-wordline driver areas SWD_ARA1-1 and SWD_ARA2-1 may be repeated in the direction −HD2.

FIG. 12B is a diagram illustrating an example of a configuration in which the sub-wordline drivers of FIG. 12A drive the wordlines of FIG. 10.

Referring to FIGS. 12A and 12B, the sub-memory cell array area SMCA_ARA1-1 and the sub-wordline driver and bitline sense amplifier area SWD_BLSA_ARA1-1 may be electrically connected by the wafer bonding interface WB_INTF. For example, the sub-memory cell array area SMCA_ARA1-1 may include a plurality of upper metal pads disposed at lower portions of memory blocks MBLK11, MBLK12, MBLK13, etc., and the sub-wordline driver and bitline sense amplifier area SWD_BLSA_ARA1-1 may include a plurality of lower metal pads disposed in lower portions of the plurality of upper metal pads. For example, through the plurality of upper metal pads and the plurality of lower metal pads, the plurality of sub-wordline driver groups may drive the plurality of wordline groups in the first direction or the second direction, as shown in FIG. 12A.

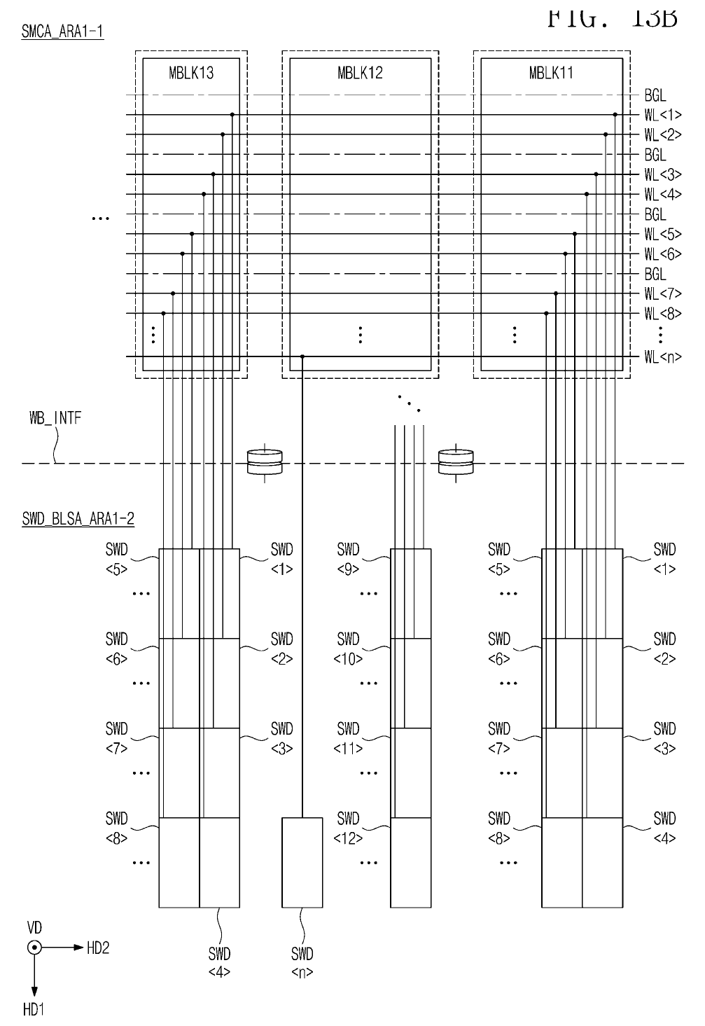

FIG. 13A is a diagram illustrating an example of a sub-wordline driver and bitline sense amplifier area, e.g., the sub-wordline driver and bitline sense amplifier area of FIG. 3B.

Referring to FIG. 13A, the sub-wordline driver and the bitline sense amplifier area SWD_BLSA_ARA1-2 may correspond to one of the sub-wordline driver and bitline sense amplifier areas SWD_BLSA_ARAa to SWD_BLSA_ARAj shown in FIG. 3B, and may correspond to the example shown in FIG. 9. Accordingly, the sub-wordline drivers SWD<1> to SWD<8> may be grouped as the sub-wordline driver group SWD_Group1, and the sub-wordline drives SWD<9> to SWD<16> may be grouped as the sub-wordline driver group SWD_Group2. In a similar manner, the remaining sub-wordline drivers SWD<17> to SWD<n> may be grouped as different sub-wordline driver groups. The example of FIG. 13A differs from the example shown in FIG. 11A only in the connection relationship between the sub-wordline driver groups and the corresponding wordlines, and thus redundant description will be omitted.

As illustrated in FIG. 13A, the sub-wordline drivers SWD<1> to SWD<8>, SWD<17> to SWD<20>, …., and SWD<n−11> to SWD<n−8> may be disposed in the sub-wordline driver area SWD_ARA1-2, and the sub-wordline drivers SWD<9> to SWD<16>, SWD<24> to SWD<27>, …, and SWD<n-3> to SWD<n> may be disposed in the sub-wordline driver area SWD_ARA2-2. The sub-wordline driver area SWD_ARA3-2 is only partially shown, and areas having the same shape as the sub-wordline driver areas SWD_ARA1-2 and SWD_ARA2-2 may be repeated in the direction −HD2.

FIG. 13B is a diagram illustrating an example of a configuration in which the sub-wordline drivers of FIG. 13A drive the wordlines of FIG. 10.

Referring to FIGS. 13A and 13B, the sub-memory cell array area SMCA_ARA1-1 and the sub-wordline driver and bitline sense amplifier area SWD_BLSA_ARA1-2 may be electrically connected by the wafer bonding interface WB_INTF. For example, the sub-memory cell array area SMCA_ARA1-1 may include a plurality of upper metal pads disposed at lower portions of memory blocks MBLK11, MBLK12, MBLK13, etc., and the sub-wordline driver and bitline sense amplifier area SWD_BLSA_ARA1-2 may include a plurality of lower metal pads disposed in lower portions of the plurality of upper metal pads. For example, through the plurality of upper metal pads and the plurality of lower metal pads, the plurality of sub-wordline driver groups may drive the plurality of wordline groups in the first direction or the second direction, as shown in FIG. 13A.

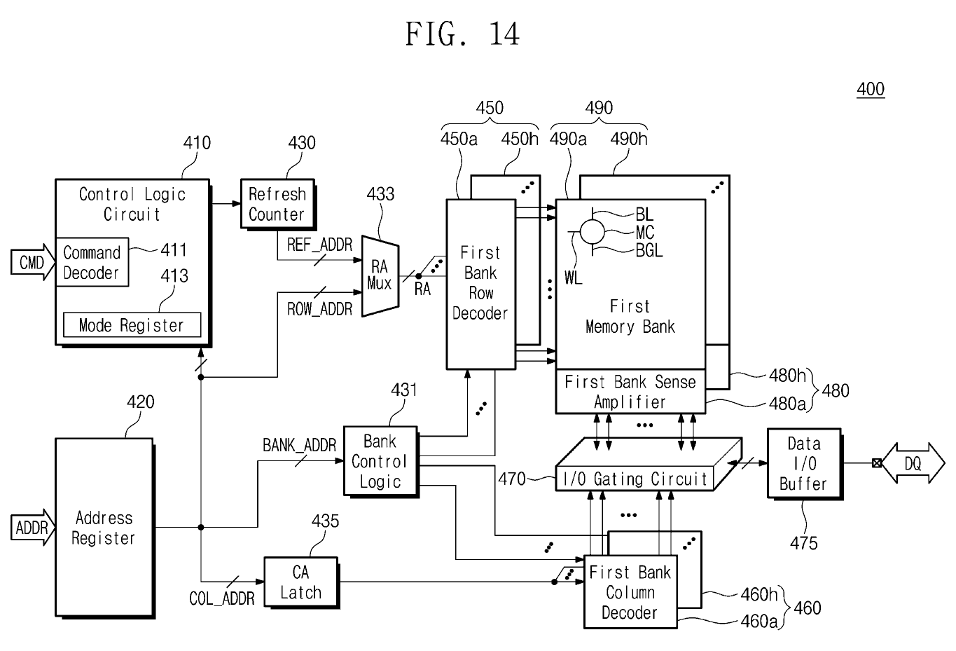

FIG. 14 is a block diagram illustrating an example of a semiconductor memory device.

Referring to FIG. 14, a semiconductor memory device 400 may include a control logic circuit 410, an address register 420, a bank control logic 431, a row address (RA) multiplexer 433, a column address (CA) latch 435, a row decoder 450, a column decoder 460, a memory cell array 490, an input/output (I/O) gating circuit 470, a sense amplifier unit 480, a data input/output buffer 475, and a refresh counter 430.

The memory cell array 490 may include first to eighth memory banks 490a to 490h. The row decoder 450 may include first to eighth bank row decoders 450a to 450h respectively connected to the first to eighth memory banks 490a to 490h, the column decoder 460 may include first to eight bank column decoders 460a to 460h respectively connected to first to eighth memory bank 490a to 490h, and the sense amplifier unit 480 may include first to eighth bank sense amplifiers 480a to 480h respectively connected to first to eighth memory banks 490a to 490h.

The first to eighth memory banks 490a to 490h, the first to eighth bank sense amplifiers 480a to 480h, the first to eight bank row decoders 450a to 450h, and the first to eighth bank column decoders 460a to 460h may constitute the first to eighth banks, respectively. Each of the first to eighth memory banks 490a to 490h may include a plurality of wordlines WLs and a plurality of bitlines BLs, and a plurality of memory cells MCs formed at points where the wordlines WLs and the bitlines BLs intersect.

Although FIG. 14 illustrates an example of a memory device 400 that includes eight banks, the memory device 400 may include any number of banks, two or more.

The address register 420 may receive an address ADDR including a bank address BANK_ADDR, a row address ROW_ADDR, and a column address COL_ADDR from a memory controller. The address register 420 may provide the received bank address BANK_ADDR to the bank control logic 431, provide the received row address ROW_ADDR to a row address multiplexer 433, and provide the received column address COL_ADDR to column address latch 435.

The bank control logic 431 may generate bank control signals in response to the bank address BANK_ADDR. In response to the bank control signals, a bank row decoder corresponding to a bank address BANK_ADDR among the first to eighth bank row decoders 450a to 450h may be activated, and a bank column decoder corresponding to the first to eighth banks column decoders 460a to 460h may be activated.

The row address multiplexer 433 may receive the row address ROW_ADDR from the address register 420 and receive the refresh row address REF_ADDR from a refresh counter 430. The row address multiplexer 433 may selectively output the row address ROW_ADDR or the refresh row address REF_ADDR as the row address RA. The row address RA output from the row address multiplexer 433 may be applied to the first to eighth bank row decoders 450a to 450h, respectively.

The bank row decoder activated by the bank control logic 431 among the first to eighth bank row decoders 450a to 450h may decode the row address RA output from the row address multiplexer 433 to activate a wordline corresponding to the row address RA. For example, the activated bank row decoder may apply a wordline driving voltage to a wordline corresponding to a row address RA. The activated bank row decoder may generate a wordline driving voltage using a power supply voltage and provide the wordline driving voltage to the corresponding wordline.

The column address latch 435 may receive the column address COL_ADDR from the address register 420 and temporarily store the received column address COL_ADDR. Also in burst mode, the column address latch 435 may incrementally increase the received column address COL_ADDR. The column address latch 435 may apply the temporarily stored or incrementally increased column address COL_ADDR to the first through eighth bank column decoders 460a to 460h, respectively.

A bank column decoder activated by the bank control logic 431 among the first to eighth bank column decoders 460a to 460h may activate a sense amplifier corresponding to the bank address BANK_ADDR and the column address COL_ADDR through the input/output gating circuit 470.

The input/output gating circuit 470 may include, along with circuits for gating input/output data, input data mask logic, read data latches for storing data output from the first to eighth memory banks 490a to 490h, and write drivers for writing data to the first to eighth memory banks 490a to 490h.

Data read from one of the first through eighth memory banks 490a to 490h may be sensed by a sense amplifier corresponding to the one memory bank and stored in the read data latches.

Data stored in the read data latches may be provided to the memory controller via a data input/output buffer 475. Data DQ to be written to one of the first to eighth memory banks 490a to 490h may be provided from the memory controller to the data input/output buffer 475. The data DQ provided to the data input/output buffer 475 may be provided to the input/output gating circuit 470.

The control logic circuit 410 may control the operation of the memory device 400. For example, the control logic circuit 410 may generate control signals to cause the memory device 400 to perform a write operation or a read operation. The control logic circuit 410 may include a command decoder 411 configured to decode a command CMD received from the memory controller, and a mode register 413 configured to set an operation mode of the memory device 400.

In some implementations, the semiconductor memory devices described with respect to FIGS. 1 to 13B may correspond to the memory device 400. The sub-memory cell array areas, and the sub-wordline driver and bitline sense amplifier areas described above with reference to FIGS. 3A and 3B may be implemented by the first to eighth memory banks 490a to 490h, and the first to eighth bank sense amplifiers 480a to 480h.

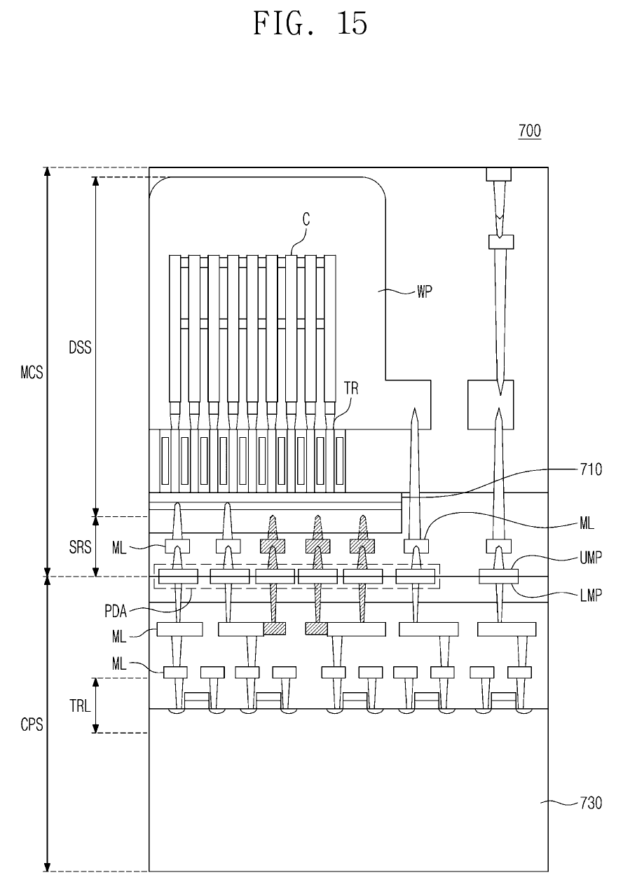

FIG. 15 is a diagram illustrating an example of a semiconductor memory device.

Referring to FIG. 15, a semiconductor memory device 700 may include a memory cell array structure MCS and a core-peripheral circuit structure CPS.

The memory cell array structure MCS may be formed on the first substrate 710. The memory cell array structure MCS may include a data storage structure DSS and a signal routing structure SRS. The data storage structure DSS may include a plurality of memory cells including capacitors C and transistors TR, a plurality of bitlines, and a plurality of wordlines. The signal routing structure SRS may include a plurality of upper metal pads UMP and a plurality of metal lines ML. The plurality of metal lines ML may provide electrical connections between the plurality of upper metal pads UMP and the data storage structure DSS. For example, the plurality of metal lines ML may provide electrical connections of bitlines with some of the plurality of upper metal pads UMP or electrical connections of wordlines with some of a plurality of upper metal pads UMP.

The core-peripheral circuit structure CPS may be formed on the second substrate 730. The core-peripheral circuit structure CPS may include a transistor layer TRL. A plurality of transistors for driving the memory cell array structure MCS may be disposed on the transistor layer TRL. Some of the plurality of transistors disposed in the transistor layer TRL may constitute bitline sense amplifiers. Another portion of the plurality of transistors disposed in the transistor layer TRL may constitute sub-wordline drivers. Another portion of the plurality of transistors disposed in the transistor layer TRL may constitute other peripheral circuits for operation of the semiconductor memory device 700.

The plurality of upper metal pads UMP and the plurality of lower metal pads LMP are disposed at positions corresponding to each other, and provide electrical connections between each configuration formed on the first substrate 710 and each configuration formed on a second substrate 750. The plurality of upper metal pads UMP and the plurality of lower metal pads LMP may constitute the pad array PDA.

In some implementations, upper metal pads and lower metal pads may be used for electrical connections between wordlines formed in the first substrate 710 and sub-wordline drivers formed in the second substrate 750, as described above with reference to FIGS. 11C, 11E, 11F, and the like.

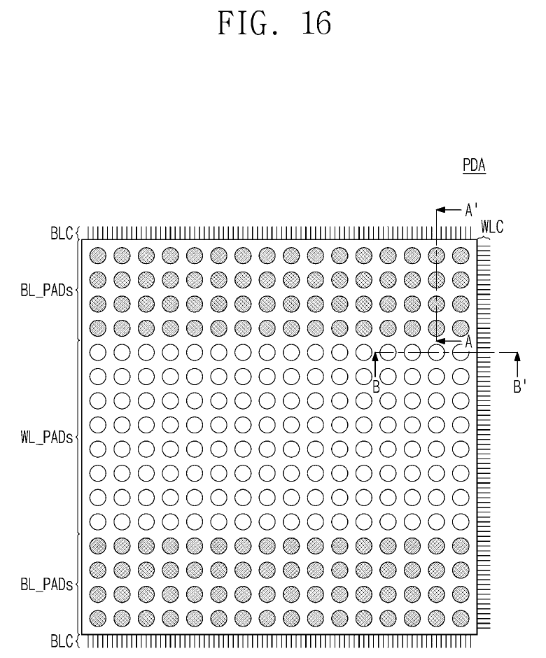

FIG. 16 is a plan view illustrating an example of a pad array, e.g., a pad array included in the semiconductor memory device of FIG. 15.

Referring to FIG. 16, the pad array PDA may include a plurality of bitline pads BL_PADs and a plurality of wordline pads WL_PADs. The pad array PDA may be one of a plurality of upper metal pads UMP and a plurality of lower metal pads LMP shown in FIG. 14.

The plurality of bitline pads BL_PADs may be disposed to be divided with the plurality of wordline pads WL_PADs interposed therebetween. The plurality of bitline pads BL_PADs may be electrically connected to the bitline connection area BLC through one or more metal layers. The bitline pads BL_PADs disposed on both sides of the plurality of wordline pads WL_PADs may be routed to adjacent bitline connection areas BLC.

The plurality of wordline pads WL_PADs may be electrically connected to the wordline connection area WLC through one or more metal layers.

The bitline connection area BLC may provide electrical connections between a plurality of bitline pads BL_PADs and bitlines included in the memory cell array. The wordline connection area WLC may provide electrical connections between a plurality of wordline pads WL_PADs and wordlines included in the memory cell array.

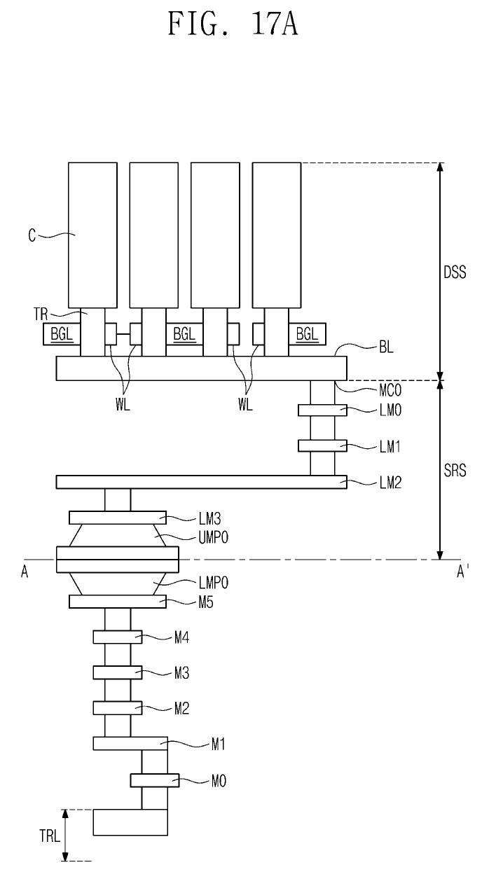

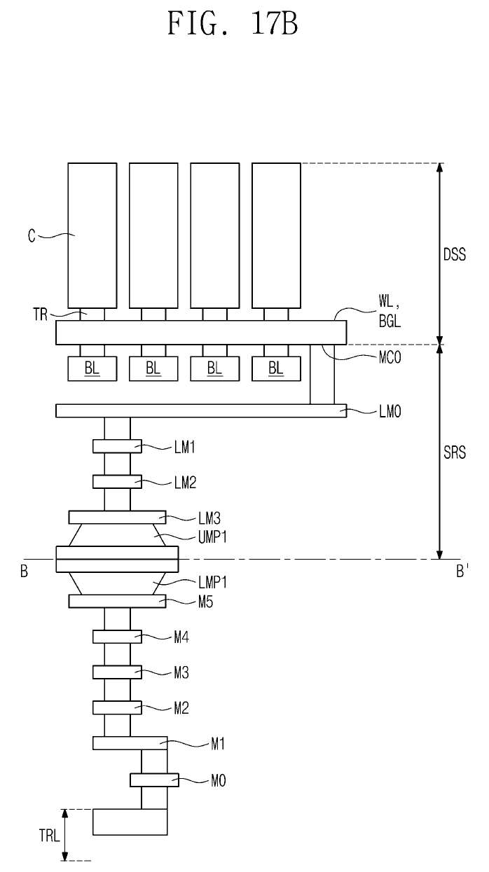

FIG. 17A is a cross-sectional view of an example of the semiconductor memory device of FIG. 16 taken along line A-A′.

Referring to FIG. 17A, bitline sense amplifiers disposed in a transistor layer TRL may be electrically connected to the bitline BL.

For convenience of description, other elements (e.g., neighboring metal pads) except for configurations that provide electrical connections between the bitline sense amplifiers disposed in the transistor layer TRL and the bitline BL, are omitted in FIG. 17A. The bitline sense amplifiers disposed in the transistor layer TRL may be electrically connected to the lower metal pad LMP through the metal layers M0, M1, M2, M3, M4, and M5. The lower metal pad LMP may be in physical and electrical contact with the upper metal pad UMP. The upper metal pad UMP may be electrically connected to a plurality of metal layers LM3, LM2, LM1, and LM0. The metal layer LM0 may be connected to the bitline BL through the metal contact MC0. The metal contact MC0 may be formed in the bitline connection area BLC of FIG. 16. The change in the potential of the bitline BL by the capacitor C and the cell transistor TR is applied to the transistor layer TRL through the plurality of metal lines LM0 to LM3, the upper metal pad UMP, the lower metal pad LMP, and the plurality of metal layers M0 to M5. The bitline sense amplifiers disposed in the transistor layer TRL may amplify a change in the potential of the bitline BL to sense data stored in the capacitor C. The data storage structure DSS may include a plurality of capacitors C, cell transistors TR, a plurality of wordlines WL, a plurality of bitlines BL, and a plurality of backgatelines BGL. The signal routing structure SRS may include a plurality of metal layers LM0 to LM3 and an upper metal pad UMP.

FIG. 17B is a cross-sectional view of an example of the semiconductor memory device of FIG. 16 taken along line B-B′.

Referring to FIG. 17B, a sub-wordline driver disposed in the transistor layer TRL may be electrically connected to the wordline WL.

For convenience of description, other elements (e.g., neighboring metal pads) are omitted in FIG. 17B except for configurations that provide electrical connections between a sub-wordline driver disposed in the transistor layer TRL and the wordline WL. The sub-wordline driver disposed in the transistor layer TRL may be electrically connected to the lower metal pad LMP through the metal layers M0, M1, M2, M3, M4, and M5. The lower metal pad LMP may be in physical and electrical contact with the upper metal pad UMP. The upper metal pad UMP may be electrically connected to a plurality of metal layers LM3, LM2, LM1, and LM0. The metal layer LM0 may be connected to the wordline WL through the metal contact MC0. The metal contact MC0 may be formed in the wordline connection area WLC of FIG. 15. The wordline driving voltage output by the sub-wordline driver may be applied to the wordline WL through the plurality of metal layers M0 to M5, the lower metal pad LMP, the upper metal pad UMP, the plurality of metal lines LM0 to LM3, and the metal contact MC0. The cell transistor TR is switched by the wordline driving voltage applied to the wordline WL, and the bitline BL and the capacitor C may be connected to each other. The data storage structure DSS may include a plurality of capacitors C, cell transistors TR, a plurality of bitlines BL, a plurality of wordlines WL, and a plurality of backgatelines BGL. The signal routing structure SRS may include a plurality of metal layers LM0 to LM3 and an upper metal pad UMP.

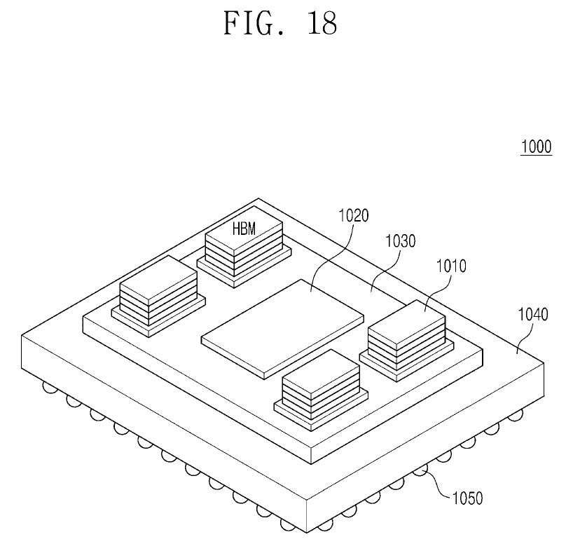

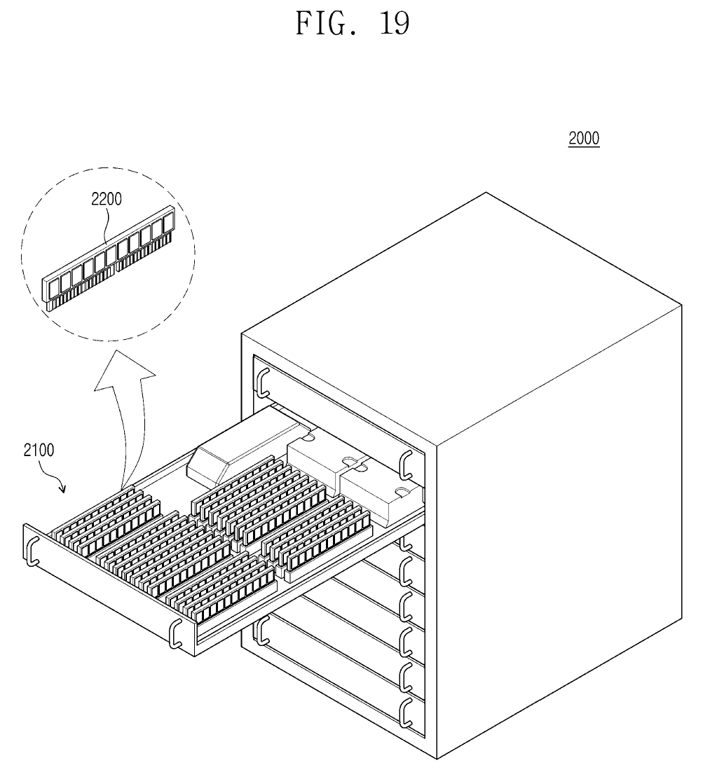

FIG. 18 is a diagram illustrating an example of a semiconductor package including a semiconductor memory device.

Referring to FIG. 18, a semiconductor package 1000 may include one or more stacked memory devices 1010 and a memory controller 1020. The stacked memory device 1010 and the memory controller 1020 may be mounted on the interposer 1030, and the interposer 1030 on which the stacked memory device 1010 and the memory controller 1020 are mounted may be mounted on a package substrate 1040. The memory controller 1020 may correspond to a semiconductor device capable of controlling functions of the stacked memory device 1010, and for example, the memory controller 1020 can be implemented as an application processor (AP).

The stacked memory device 1010 may be implemented in various forms, and, in some implementations, the stacked memory device 1010 may be a memory device in the form of a high bandwidth memory (HBM) in which a plurality of layers are stacked. Thus, the stacked memory device 1010 includes a buffer die and a plurality of memory dies, one or more of which may be implemented with a memory device in accordance with examples of the present disclosure described above with reference to FIGS. 1 to 17B.

Multiple stacked memory devices 1010 may be mounted on the interposer 1030, and the memory controller 1020 may communicate with the multiple stacked memory device 1010. Here, the interposer 1030 may include an embedded multi-die interconnect bridge (EMIB) of a silicon (TSV) type, an organic PCB type, or a Non-TSV type.

FIG. 19 is a diagram illustrating an example of an electronic system including a semiconductor memory device.

Referring to FIG. 19, the electronic system 2000 may be a server system including a plurality of server racks. One of the plurality of server racks 2100 may be illustratively shown in FIG. 19.

Each of the plurality of server racks may include one or more memory systems. For example, one server rack 2100 may include one or more memory systems. The one or more memory systems may include the semiconductor memory devices described above with reference to FIGS. 1 to 17B. In FIG. 19, one or more memory modules 2200 included in one server rack 2100 are shown.

The server rack 2100 may further include a memory module 2200, as well as the sub-wordline drivers shown in FIG. 1, the metal pads, and the vertical connection structure shown in FIG. 11C. The one or more memory systems may be connected without a chipset with at least one processor included in the server rack 2100. For example, the memory system may be a volatile memory module implemented in the form of a dual in-line memory module (DIMM). In this example, the one or more memory systems may communicate with the processor by being coupled to a DIMM socket that is electrically coupled with the processor. By way of example, memory systems may communicate with a memory controller in accordance with an interface convention defined based on a DIMM specification and operating in a DDR manner and an electronic system 2000 including the memory systems may communicate via a CXL interface with an external host device including the memory controller.

As described above, a semiconductor memory device according to some implementations of the present disclosure may have a VCAT structure and a COP structure, and may drive wordline groups obtained by dividing wordlines by sub-wordline driver groups obtained by dividing sub-wordline drivers. Each of the sub-wordline driver groups may include sub-wordline drivers that are multiples of two, each of the wordline groups may include wordlines that are multiples of two, and when one of the sub- wordline driver groups drives one of the wordline group in the first direction, another sub-wordline driver group adjacent to the sub-wordline driver group driving in the first direction may drive the other one of the wordline groups in the second direction. A backgateline disposed between different wordline groups can reduce coupling noise between wordlines disposed in different wordline groups, thereby improving refresh characteristics of the semiconductor memory device, based on the recognition that coupling noise is not a major problem in wordlines that are driven in the same direction and that are placed in the same wordline group.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to examples thereof, it will be apparent to those of ordinary skill in the art that various changes and modifications may be made thereto without departing from the spirit and scope of the present disclosure as set forth in the following claims.

What is claimed is:

1. A semiconductor memory device comprising:
a first semiconductor die; and
a second semiconductor die, the first semiconductor die and the second semiconductor die being stacked in a vertical direction,
wherein the first semiconductor die includes:
a first wordline group including a first plurality of wordlines that are adjacent to each other;
a second wordline group including a second plurality of wordlines that are adjacent to each other; and
a first backgateline between the first wordline group and the second wordline group,
wherein the second semiconductor die includes:
a first sub-wordline driver group configured to drive the first wordline group; and
a second sub-wordline driver group configured to drive the second wordline group.

2. The semiconductor memory device of claim 1, wherein:
the first sub-wordline driver group includes a first plurality of sub-wordline drivers that are configured to respectively drive the first plurality of wordlines included in the first wordline group; and
the second sub-wordline driver group includes a second plurality of sub-wordline drivers that are configured to respectively drive the second plurality of wordlines included in the second wordline group.

3. The semiconductor memory device of claim 2, wherein:
a number of the first plurality of wordlines included in the first wordline group is equal to a number of the second plurality of wordlines included in the second wordline group.

4. The semiconductor memory device of claim 1, wherein:
the first sub-wordline driver group is configured to drive the first plurality of wordlines in a first direction that is an extension direction of the first plurality of wordlines; and
the second sub-wordline driver group is configured to drive the second plurality of wordlines in a second direction opposite to the first direction.

5. The semiconductor memory device of claim 1, wherein the first plurality of wordlines and the second plurality of wordlines are each a number of wordlines that is a multiple of two.

6. The semiconductor memory device of claim 1, wherein:
the first semiconductor die includes a plurality of sub-memory cell arrays;
the second semiconductor die is below the first semiconductor die;
each of the plurality of sub-memory cell arrays includes a plurality of memory blocks; and
the first sub-wordline driver group and the second sub-wordline driver group are arranged below different ones of the plurality of memory blocks.

7. The semiconductor memory device of claim 6, wherein:
the plurality of memory blocks include:
a first memory block; and
a second memory block arranged in a horizontal direction with respect to the first memory block,
wherein the first sub-wordline driver group is arranged below the first memory block; and
wherein the second sub-wordline driver group is arranged below the second memory block.

8. The semiconductor memory device of claim 7, wherein:
the first semiconductor die includes:
a third wordline group comprising a third plurality of wordlines adjacent to each other, wherein the second wordline group is between the first wordline group and the third wordline group; and
a second backgateline between the second wordline group and the third wordline group,
wherein the second semiconductor die includes a third sub-wordline driver group configured to drive the third wordline group.

9. The semiconductor memory device of claim 8, wherein the third sub-wordline driver group is arranged below the first memory block.

10. The semiconductor memory device of claim 9, wherein:
the first to third sub-wordline driver groups are arranged in a zigzag manner along a third direction,
wherein the third direction is a horizontal direction perpendicular to a first direction, and
wherein the first direction is an extension direction of the first plurality of wordlines and the second plurality of wordlines.

11. The semiconductor memory device of claim 6, wherein:
each of the plurality of memory blocks includes a plurality of memory cells; and
each of the plurality of memory cells includes a vertical channel transistor.

12. The semiconductor memory device of claim 7, wherein:
the first semiconductor die includes a plurality of first upper metal pads arranged below the first memory block;
the second semiconductor die includes a plurality of first lower metal pads arranged below the plurality of first upper metal pads; and
the first sub-wordline driver group is configured to drive the first wordline group through metal pads of the plurality of first upper metal pads and of the plurality of first lower metal pads.

13. The semiconductor memory device of claim 12, wherein:
the first semiconductor die includes a plurality of second upper metal pads arranged below the second memory block;
the second semiconductor die includes a plurality of second lower metal pads arranged below the plurality of second upper metal pads; and
the second sub-wordline driver group is configured to drive the second wordline group through metal pads of the plurality of second upper metal pads and of the plurality of second lower metal pads.

14. The semiconductor memory device of claim 13, wherein:
the first semiconductor die includes:
a third wordline group comprising a third plurality of wordlines adjacent to each other, wherein the second wordline group is between the first wordline group and the third wordline group; and
a second backgateline between the second wordline group and the third wordline group; and
the second semiconductor die includes:
a third sub-wordline driver group configured to drive the third wordline group,
wherein the third sub-wordline driver group is configured to drive the third wordline group through second metal pads of the plurality of first upper metal pads and of the plurality of first lower metal pads.

15. A method of operating a semiconductor memory device, the method comprising:
driving, by a first sub-wordline driver group, a first wordline group comprising a first plurality of wordlines that are adjacent to each other and number a multiple of two; and
driving, by a second sub-wordline driver group, a second wordline group comprising a second plurality of wordlines that are adjacent to each other and number a multiple of two,
wherein a first backgateline is between the first wordline group and the second wordline group.

16. The method of claim 15, further comprising:
driving, by a third sub-wordline driver group, a third wordline group,
wherein the second wordline group is between the first wordline group and the third wordline group,
wherein the third wordline group includes a third plurality of wordlines that are adjacent to each other and number a multiple of two, and
wherein a second backgateline is between the second wordline group and the third wordline group.

17. The method of claim 16, wherein:
the first to third sub-wordline driver groups are arranged in a zigzag manner along a third direction,
the third direction is a horizontal direction perpendicular to a first direction, and
the first direction is an extension direction of the first plurality of wordlines and the second plurality of wordlines.

18. A semiconductor memory system comprising:
a memory controller; and
a semiconductor memory device configured to operate under control of the memory controller,
wherein the semiconductor memory device includes:
a first semiconductor die; and
a second semiconductor die, the first semiconductor die and the second semiconductor die being stacked in a vertical direction,
wherein the first semiconductor die includes:
odd-numbered wordline groups, each odd-numbered wordline group of the odd-numbered wordline groups including a corresponding first plurality of wordlines that are adjacent to each other and number a multiple of two;
even-numbered wordline groups, each even-numbered wordline group of the even-numbered wordline groups including a corresponding second plurality of wordlines that are adjacent to each other and number a multiple of two,
wherein the odd-numbered wordline groups and the even-numbered wordlines groups alternate with one another along a horizontal direction; and
a plurality of backgatelines arranged between the odd-numbered wordline groups and the even-numbered wordlines groups, and
wherein the second semiconductor die includes:
odd-numbered sub-wordline driver groups configured to drive the odd-numbered wordline groups; and
even-numbered sub-wordline driver groups configured to drive the even-numbered wordline groups.

19. The semiconductor memory system of claim 18, wherein:
each of the odd-numbered sub-wordline driver groups includes a first plurality of sub-wordline drivers that number a multiple of two;
each of the even-numbered sub-wordline driver groups includes a second plurality of sub-wordline drivers that number a multiple of two;
the odd-numbered sub-wordline driver groups and the even-numbered sub-wordline driver groups are arranged in a zigzag manner along a third direction;
the third direction is a horizontal direction perpendicular to a first direction; and
the first direction is an extension direction of wordlines of the odd-numbered wordline groups and the even-numbered wordline groups.

20. The semiconductor memory system of claim 18, wherein:
the first semiconductor die includes a plurality of sub-memory cell arrays;
each of the plurality of sub-memory cell arrays includes a plurality of memory blocks; and
the odd-numbered sub-wordline driver groups and the even-numbered sub-wordline driver groups are arranged below different ones of the plurality of memory blocks.
